(19) United States
(12) Patent Application Publication
(10) Pub. No.: US 2025/0098153 A1
(43) Pub. Date: Mar. 20, 2025

(54) SEMICONDUCTOR DEVICE

(71) Applicant: Samsung Electronics Co., Ltd., Suwon-si (KR)

(72) Inventors: Taegyu Kang, Suwon-si (KR); Joongchan Shin, Suwon-si (KR); Keunui Kim, Suwon-si (KR); Myeongseon Kim, Suwon-si (KR); Eunsuk Jang, Suwon-si (KR)

(21) Appl. No.: 18/657,892

(22) Filed: May 8, 2024

(30) Foreign Application Priority Data
Sep. 19, 2023 (KR) 10-2023-0124714

(51) Int. Cl. H10B 12/00

(52) U.S. Cl. CPC H10B 12/482; H10B 12/02; H10B 12/315; H10B 12/50

(57) ABSTRACT

A semiconductor device includes: a bit line on a substrate and extending in a first direction; a first word line on the bit line extending in a second direction crossing the first direction; a second word line extending in the second direction on the bit line and spaced from the first word line; first activating patterns on the bit line between the first and second word lines; second activating patterns on the bit line between the first and second word lines; a back gate electrode crossing the bit line and extending in the second direction between the first and second activating patterns; and first and second back gate capping patterns overlapping the back gate electrode. The first back gate capping pattern defines a gap region on the back gate electrode not overlapping the first and second activating patterns, and the second back gate capping pattern is in the gap region.

### CROSS-REFERENCE TO RELATED APPLICATION(S)

This application claims priority under 35 U.S.C. § 119 to and the benefit of Korean Patent Application No. 10-2023-0124714 filed in the Korean Intellectual Property Office on Sep. 19, 2023, the entire contents of which are incorporated herein by reference.

### BACKGROUND

The present disclosure relates generally to a semiconductor device.

It is often desirable to increase integration of semiconductor memory devices so as to satisfy prescribed performance criteria and to reduce device cost. The semiconductor memory devices particularly require increased integration because its integration is an important factor for determining the price of the product.

The integration of two-dimensional (2D) or surface semiconductor memory devices is generally determined by an area of a unit memory cell so it is substantially influenced by dimensional scaling and levels of skills for forming fine patterns. However, very expensive equipment is needed to generate fine patterns, so even when the integration of the 2D semiconductor memory devices increases, a corresponding reduction in overall device cost may not be readily achieved.

### SUMMARY

The present disclosure has been made in an effort to provide a semiconductor device with improved reliability and productivity. In order to reduce overall device costs, aspects of the inventive concept, as manifested in one or more embodiments thereof, provide semiconductor memory devices that include vertical channel transistors having channels that extend vertically.

An embodiment of the present disclosure provides a semiconductor device including: a substrate; a bit line on the substrate and extending in a first direction parallel to an upper surface of the substrate; a first word line on the bit line, the first word line extending in a second direction parallel to the upper surface of the substrate and crossing the first direction; a second word line on the bit line, the second word line extending in the second direction and spaced from the first word line in the first direction; first activating patterns on the bit line and spaced in the second direction between the first word line and the second word line; second activating patterns on the bit line and spaced from the first activating patterns in the first direction between the first word line and the second word line; a back gate electrode crossing the bit line and extending in the second direction between the first activating patterns and the second activating patterns; and a first back gate capping pattern and second back gate capping pattern at least partially overlapping the back gate electrode in a plan view, wherein the first back gate capping pattern defines a gap region on the back gate electrode not overlapping the first activating patterns and the second activating patterns in the first direction, and the second back gate capping pattern is in the gap region.

Another embodiment of the present disclosure provides a semiconductor device including: a substrate; bit lines on the substrate and extending in a first direction parallel to an upper surface of the substrate; word lines on the bit lines and extending in a second direction parallel to the upper surface of the substrate and crossing the first direction and spaced in the first direction; activating patterns on the bit lines and spaced apart from one another in the first direction and the second direction between the word lines; a back gate electrode crossing the bit lines between the activating patterns and extending in the second direction; and a first back gate capping pattern and a second back gate capping pattern at least overlapping the back gate electrode, wherein each of the respective word lines includes a body portion extending in the second direction; and protrusions extending from the body portion in the first direction toward the back gate electrode and between the activating patterns spaced in the second direction, and wherein the first back gate capping pattern defines a gap region between the protrusions spaced in the first direction on the back gate electrode, and the second back gate capping pattern is in the gap region.

Another embodiment of the present disclosure provides a semiconductor device including: a substrate; a peripheral circuit structure body including peripheral circuits on the substrate and a peripheral circuit insulation layer at least partially covering the peripheral circuits; bit lines on the peripheral circuit structure body and extending in a first direction parallel to an upper surface of the substrate; word lines on the bit lines and extending in a second direction parallel to the upper surface of the substrate and crossing the first direction on the bit lines, the word lines spaced apart from each other in the first direction; activating patterns on the bit lines and between the word lines, the activating patterns spaced apart from each other in the first direction and the second direction; a back gate electrode crossing the bit lines between the activating patterns and extending in the second direction; and a first back gate capping pattern and a second back gate capping pattern at least partially overlapping the back gate electrode and including different materials, wherein each of the word lines include a body portion extending in the second direction, and protrusions extending from the body portion in the first direction toward the back gate electrode and between the activating patterns spaced in the second direction, each of the back gate electrode and the word lines respectively includes a first surface and a second surface opposite the first surface, the first surface facing the bit lines and the second surface facing the first surface in a vertical direction, the first surfaces of the word lines are nearer to the bit lines than the first surface of the back gate electrode, the first back gate capping pattern includes a first portion at least partially covering the first surface of the back gate electrode, and second portions extending in a vertical direction from the first portion and spaced in the first direction with the second back gate capping pattern therebetween, the first back gate capping pattern includes a gap region between the protrusions and defined by the first portion of the first back gate capping pattern and the second portions adjacent to each other, and the second back gate capping pattern is in the gap region.

According to one or more embodiments, since the back gate capping patterns are formed on the back gate electrode, exposure of the back gate electrode or damage to the back gate electrode may be prevented when the word line is formed, thereby improving productivity and reliability of the semiconductor device.

### BRIEF DESCRIPTION OF THE DRAWINGS

FIG. 1 shows a top plan view of a semiconductor device according to one or more embodiments.

FIG. 2 shows a cross-sectional view with respect to lines A-A′, B-B′, and C-C′ of FIG. 1.

FIG. 3 shows a partially enlarged view of a region R1 of FIG. 2.

FIG. 4 shows a partially enlarged view of a region R2 of FIG. 2.

FIG. 5 to FIG. 8 show top plan views of a semiconductor device corresponding to a level of a line X1-X1′ of FIG. 3 and FIG. 4, according to one or more embodiments.

FIG. 9 to FIG. 11, FIG. 13, FIG. 15, and FIG. 17 show partially enlarged views of cross-sections of a semiconductor device, according to one or more embodiments.

FIG. 12 shows a top plan view of a semiconductor device corresponding to a level of a line X1-X1′ of FIG. 11.

FIG. 14 shows a top plan view of a semiconductor device corresponding to a level of a line X1-X1′ of FIG. 13.

FIG. 16 shows a top plan view of a semiconductor device corresponding to a level of a line X1-X1′ of FIG. 15.

FIG. 18 to FIG. 23, FIG. 25, FIG. 27, and FIG. 29 to FIG. 33 show cross-sectional views of intermediate processes in an example method for manufacturing a semiconductor device according to one or more embodiments.

FIG. 24 shows a top plan view of a semiconductor device corresponding to a level of a line X1-X1′ of FIG. 23.

FIG. 26 shows a top plan view of a semiconductor device corresponding to a level of a line X1-X1′ of FIG. 25.

FIG. 28 shows a top plan view of a semiconductor device corresponding to a level of a line X1-X1′ of FIG. 27.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Parts that are irrelevant to the description will be omitted to clearly describe the present disclosure, and the same elements will be designated by the same reference numerals throughout the specification.

The sizes and thicknesses of elements for each configuration shown in the drawings are arbitrarily shown for better understanding and ease of description, but the present invention is not limited thereto. In the drawings, the thicknesses of layers, films, panels, regions, etc., may be enlarged for clarity. The thicknesses of some layers and areas may be exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

The phrase “in a plan view” means viewing an object portion from the top or bottom (i.e., in a horizontal plane), and the phrase “in a cross-sectional view” means viewing a cross-section of which the object portion is vertically cut from the side.

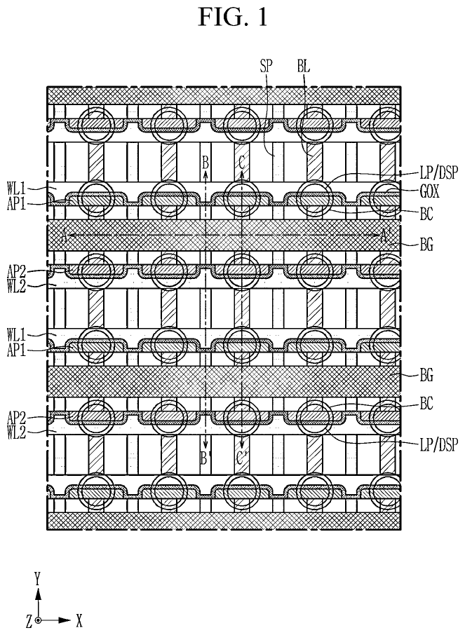

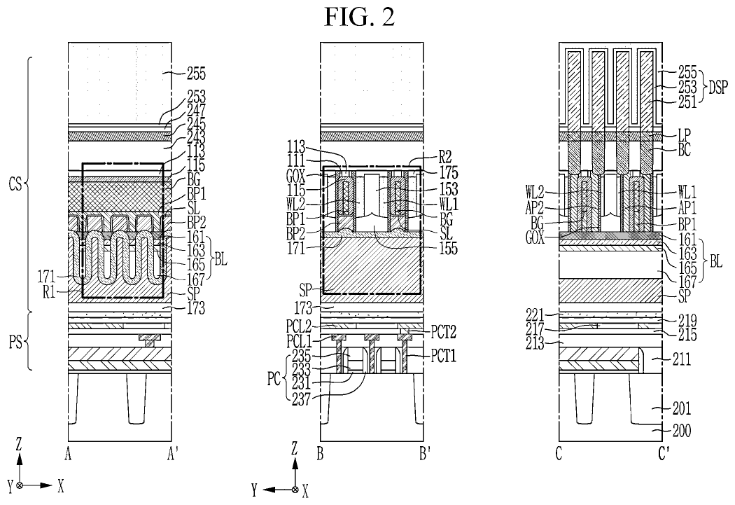

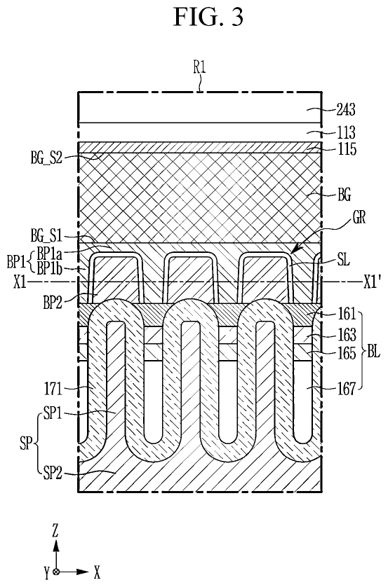

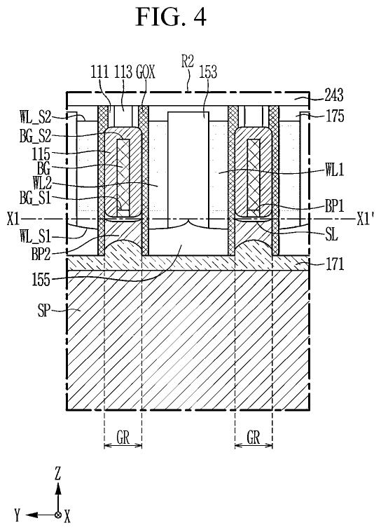

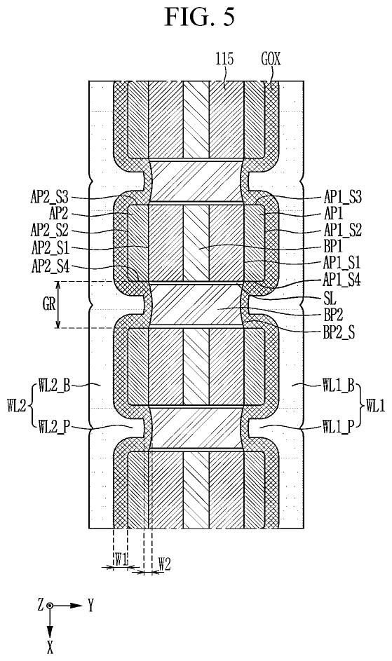

FIG. 1 shows a top plan view of a semiconductor device according to several embodiments. FIG. 2 shows a cross-sectional view with respect to lines A-A′, B-B′, and C-C′ of FIG. 1. FIG. 3 shows a partially enlarged view of a region R1 of FIG. 2. FIG. 4 shows a partially enlarged view of a region R2 of FIG. 2. FIG. 5 to FIG. 8 show top plan views of a semiconductor device corresponding to a level of a line X1-X1′ of FIG. 3 and FIG. 4 according to one or more embodiments.

The semiconductor device according to embodiments of the present disclosure may include memory cells including vertical channel transistors (VCT).

Referring to FIG. 1 to FIG. 8, the semiconductor device according to several embodiments may include a substrate 200, a peripheral circuit structure body (PS) disposed on the substrate 200, and a cell array structure body (CS) disposed on the peripheral circuit structure body PS.

The substrate 200 may include a cell array region and a peripheral circuit region. Memory cells may be disposed in the cell array region of the substrate 200. FIG. 1 shows the cell array region of the substrate 200, which will now be described in detail.

The substrate 200 may be a silicon substrate, or may include other materials, for example, silicon germanium, indium antimonide, lead telluride compound, indium arsenic, indium phosphide, gallium arsenic, and gallium antimonide, and without being limited thereto, and the materials included by the substrate 200 are diverse.

An isolation layer 201 may be disposed in the substrate 200. The isolation layer 201 may define an active region in the substrate 200. For example, the isolation layer 201 may have a shallow trench isolation (STI) structure with an excellent isolating characteristic.

The isolation layer 201 may include an insulating material. For example, the isolation layer 201 may include a silicon oxide, a silicon nitride, and combinations thereof. However, materials and structures of the isolation layer 201 are not limited thereto and may be modifiable in many ways.

The peripheral circuit structure body PS may be disposed on the substrate 200. The peripheral circuit structure body PS may be disposed between the substrate 200 and the cell array structure body CS.

The peripheral circuit structure body PS may be disposed in the cell array region and the peripheral circuit region of the substrate 200. That is, a portion of the peripheral circuit structure body PS may be disposed in the cell array region of the substrate 200, and another portion thereof may be disposed in the peripheral circuit region.

The peripheral circuit structure body PS may include a peripheral circuit (PC), peripheral contact plugs PCT1 and PCT2, peripheral circuit wires PCL1 and PCL2, peripheral circuit insulation layers 211, 213, 215, 217, and 219, and a bonding insulation layer 221.

The peripheral circuit PC may, for example, be a sensing transistor, a transmitting transistor, and/or a driving transistor. As used herein, the term “and/or” is intended to include any and all combinations of one or more of the associated listed items. However, types of the transistors of the peripheral circuit PC may be modifiable in many ways according to design disposition of the semiconductor device.

The peripheral circuit PC may be disposed on the substrate. The peripheral circuit PC may include a peripheral circuit gate insulating layer 231, a first peripheral circuit conductive pattern 233, and a second peripheral circuit conductive pattern 235 that are sequentially stacked on the substrate 200 in a vertical direction (Z direction) perpendicular to an upper surface of the substrate 200, and a peripheral circuit spacer 237 on sidewalls of the peripheral circuit gate insulating layer 231, the first peripheral circuit conductive pattern 233 and the second peripheral circuit conductive pattern 235.

The peripheral circuit gate insulating layer 231 may include a silicon oxide, a silicon oxynitride, a high dielectric constant (high-k) material having a dielectric constant that is greater than that of silicon oxide, or combinations thereof. The high dielectric constant material may, for example, include at least one of a metal oxide, a metal oxynitride, a metal silicon oxide, and a metal silicon oxynitride, but is not limited thereto.

The first peripheral circuit conductive pattern 233 and the second peripheral circuit conductive pattern 235 may respectively include a conducting material. For example, the first peripheral circuit conductive pattern 233 and the second peripheral circuit conductive pattern 235 may include at least one of a respectively doped semiconductor material, a conductive metal nitride, a conductive metal silicon nitride, a metal carbonitride, a conductive metal silicide, a conductive metal oxide, a two-dimensional (2D) material, and a metal.

In several embodiments, the two-dimensional material may be a metallic material and/or a semiconductor material. The two-dimensional material may include a two-dimensional allotrope or a two-dimensional compound, for example, it may include at least one of graphene, molybdenum disulfide (MoS2), molybdenum diselenide (MoSe2), tungsten diselenide (WSe2), and tungsten disulfide (WS2), but is not limited thereto.

FIG. 2 shows that the peripheral circuit PC includes two conductive patterns, and without being limited thereto, the peripheral circuit PC may have a single pattern or at least three conductive patterns.

The peripheral circuit spacer 237 may be on a side of the peripheral circuit PC. The peripheral circuit spacer 237 may include an insulating material. For example, the peripheral circuit spacer 237 may include a silicon oxide layer, a silicon nitride layer, a silicon oxynitride layer, and/or a low dielectric layer.

The first peripheral circuit insulation layer 211 and the second peripheral circuit insulation layer 213 may cover the peripheral circuit PC. The term “cover” (or “covering,” or like terms), as may be used herein, is intended to broadly refer to an element, structure or layer that is on or over another element, structure or layer, either directly or with one or more other intervening elements, structures or layers therebetween. That is, the first peripheral circuit insulation layer 211 may cover a side of the peripheral circuit PC, and the second peripheral circuit insulation layer 213 may cover an upper side (i.e., upper or top surface) of the peripheral circuit PC. The first peripheral circuit insulation layer 211 and the second peripheral circuit insulation layer 213 may respectively include an insulating material.

The first peripheral contact plugs PCT1 may be disposed in the first peripheral circuit insulation layer 211 and the second peripheral circuit insulation layer 213, and the first peripheral circuit wires PCL1 may be disposed in the second peripheral circuit insulation layer 213. The first peripheral circuit wires PCL1 and the first peripheral contact plugs PCT1 may be connected to the peripheral circuit PC. Although not shown in FIG. 2, the first peripheral circuit wires PCL1 may be connected to source/drain regions on at least one side of the peripheral circuit PC through the first peripheral contact plugs PCT1.

The third peripheral circuit insulation layer 215 and the fourth peripheral circuit insulation layer 217 may be sequentially disposed on the second peripheral circuit insulation layer 213.

The second peripheral contact plugs PCT2 may be in the third peripheral circuit insulation layer 215, and the second peripheral circuit wires PCL2 may be in the fourth peripheral circuit insulation layer 217. The first peripheral circuit wire PCL1 and the second peripheral circuit wire PCL2 may be connected by the second peripheral contact plug PCT2. The term “connected” (or “connecting,” or like terms such as “contact” or “contacting”), as may be used herein, is intended to refer to a physical and/or electrical connection between two or more elements, and may include other intervening elements.

The fifth peripheral circuit insulation layer 219 may be on the fourth peripheral circuit insulation layer 217, and may cover the second peripheral circuit wires PCL2.

The respective peripheral circuit insulation layers 211, 213, 215, 217, and 219 may include an insulating material. For example, the respective peripheral circuit insulation layers 211, 213, 215, 217, and 219 may include a silicon oxide layer, a silicon nitride layer, a silicon oxynitride layer, and/or a low dielectric layer. However, they are not limited thereto.

The peripheral contact plugs PCT1 and PCT2 and the peripheral circuit wires PCL1 and PCL2 may respectively include a conductive material.

The bonding insulation layer 221 may be on the fifth peripheral circuit insulation layer 219. The bonding insulation layer 221 may generally cover an upper side of the fifth peripheral circuit insulation layer 219. The bonding insulation layer 221 may include an insulating material. For example, the bonding insulation layer 221 may include a silicon carbonitride (SiCN).

The cell array structure body CS may be on the peripheral circuit structure body PS. That is, the cell array structure body CS may overlap the peripheral circuit structure body PS in a third direction Z that is a vertical direction. However, an arrangement relationship of the cell array structure body CS and the peripheral circuit structure body PS is not limited thereto and may be modifiable in many ways. For example, the cell array structure body CS may be adjacently in parallel to the peripheral circuit structure body PS in a horizontal direction. The term “overlap” (or “overlapping,” or like terms), as may be used herein, is intended to broadly refer to a first element that intersects with at least a portion of a second element in the vertical direction (i.e., Z direction) perpendicular to the upper surface of the substrate 200, but does not require that the first and second elements be completely aligned with one another in a horizontal plane (i.e., in a first direction X and/or a second direction Y).

The cell array structure body CS may, as described above, include memory cells including vertical channel transistors VCT.

The cell array structure body CS may include bit lines BL, a shield pattern SP, first and second activating patterns AP1 and AP2, first and second word lines WL1 and WL2, back gate electrodes BG, and first and second back gate capping patterns BP1 and BP2.

The bit lines BL may extend in parallel to each other in the second direction Y crossing the first direction X, the first and second directions being parallel to the upper surface of the substrate 200 (i.e., in a horizontal plane). The bit lines BL may be spaced from each other in the first direction X on the substrate 200.

Although not shown in FIG. 1, the bit lines BL may extend in the second direction Y to reach the peripheral circuit region in the cell array region. Hence, ends of the bit lines BL may be disposed in the peripheral circuit region.

The respective bit lines BL may include a polysilicon layer 161, a first metal layer 163, a second metal layer 165, and a bit line hard mask layer 167 that are sequentially stacked in the vertical direction (third direction Z).

The polysilicon layer 161 may include polysilicon to which impurities are doped, and the first metal layer 163 and the second metal layer 165 may include a conductive material. For example, the first metal layer 163 may include a conductive metal nitride (e.g., a titanium nitride and a tantalum nitride), and the second metal layer 165 may include a metal (e.g., tungsten, titanium, tantalum, etc.). At least one of the first metal layer 163 and the second metal layer 165 may include a metal silicide such as a titanium silicide, a cobalt silicide, or a nickel silicide. However, the material included by the first metal layer 163 and the second metal layer 165 is not limited thereto, and may be changeable in many ways.

The bit line hard mask layer 167 may include an insulating material such as a silicon nitride or a silicon oxynitride, although embodiments are not limited thereto.

In several embodiments, the bit lines BL may include two-dimensional and three-dimensional materials, for example, they may include graphene that is a carbon-based two-dimensional material, a carbon nanotube that is a three-dimensional material, or a combination thereof.

The bit lines BL may be disposed near the peripheral circuit structure body PS. As the bit lines BL are disposed near the peripheral circuit structure body PS, an electrical connecting path between the bit lines BL and the peripheral circuits PC may be reduced.

The shield pattern SP may be between the peripheral circuit structure body PS and the bit lines BL. The shield pattern SP may be between the bit lines BL, and may extend in the second direction Y. That is, the shield pattern SP and the bit lines BL may be alternately arranged in the first direction X.

The semiconductor device according to several embodiments may further include a spacer insulation layer 171 for defining gap regions between the bit lines BL.

The spacer insulation layer 171 may have a substantially uniform cross-sectional thickness and may be conformally disposed in the bit lines BL. The spacer insulation layer 171 may cover respective sides and upper sides of the bit lines BL. The spacer insulation layer 171 may define the gap regions between the bit lines BL. The gap regions of the spacer insulation layer 171 may extend in the second direction Y to be parallel to the bit lines BL.

The shield pattern SP may comprise a conducting material, and may include, for example, a metallic material such as tungsten (W), titanium (Ti), nickel (Ni), or cobalt (Co). For another example, the shield pattern SP may include a conductive two-dimensional material such as graphene.

The spacer insulation layer 171 may, for example, include a silicon oxide layer, a silicon nitride layer, a silicon oxynitride layer, and/or a low dielectric layer, although embodiments are not limited thereto.

The shield pattern SP may be on the spacer insulation layer 171, and may be in the gap region of the spacer insulation layer 171. That is, the shield pattern SP may fill the gap region of the spacer insulation layer 171. The term “fill” (or “fills,” or like terms), as may be used herein, is intended to refer broadly to either completely filling a defined space (e.g., the gap region of the spacer insulation layer 171) or partially filling the defined space; that is, the defined space need not be entirely filled but may, for example, be partially filled or have voids or other spaces or materials throughout.

As shown in FIG. 3, the shield pattern SP may include line portions SP1 disposed among the bit lines BL neighboring each other, and a connector SP2 for connecting the line portions SP1 in common.

In detail, the line portions SP1 of the shield pattern SP may be disposed among the bit lines BL, and may fill the gap regions of the spacer insulation layer 171. Accordingly, the line portions SP1 of the shield pattern SP may be spaced from sides of the bit lines BL in the first direction X with the spacer insulation layer 171 therebetween.

FIG. 3 shows that a height of the bit line BL in the third direction Z is greater than a height of the line portion SP1 of the shield pattern SP in the third direction Z, and without being limited thereto, the height of the bit line BL in the third direction Z may be substantially equal to or greater than the height of the line portion SP1 of the shield pattern SP in the third direction Z.

The connector SP2 of the shield pattern SP may be connected to the line portions SP1, and may be integrally formed with the line portions SP1. The term “integrally formed” (or “integrally,” or like terms) as used herein is intended to broadly refer to an element or part that is formed as a unit with one or more other elements or parts, each of the elements or parts being essential for completeness of the unit in terms of form and/or function. The connector SP2 of the shield pattern SP may be disposed on the line portions SP1, and may connect the line portions SP1, disposed among the adjacent bit lines BL, to each other. In some embodiments, the line portions SP1 and the connector SP2 of the shield pattern SP may be formed of the same material. However, without being limited thereto, in several embodiments, the line portions SP1 of the shield pattern SP and the connector SP2 may be configured with individual components.

Although not shown in FIG. 1, the connector SP2 of the shield pattern SP may be disposed in the cell array region and the peripheral circuit region. That is, the connector SP2 of the shield pattern SP may extend to reach the peripheral circuit region from the cell array region. Hence, an end of the connector SP2 of the shield pattern SP may be disposed in the peripheral circuit region.

The semiconductor device according to several embodiments may further include a shield capping pattern 173 on the shield pattern SP. The shield capping pattern 173 may directly contact the bonding insulation layer 221.

The shield capping pattern 173 may have a substantially uniform cross-sectional thickness, and may at least partially cover the shield pattern SP. The shield capping pattern 173 may, for example, include a silicon oxide layer, a silicon nitride layer, a silicon oxynitride layer, and/or a low dielectric constant (low-k) layer, although embodiments are not limited thereto.

The first activating patterns AP1 and the second activating patterns AP2 may be disposed in the respective bit lines BL. The first activating patterns AP1 and the second activating patterns AP2 may be alternately disposed in the second direction Y.

The first activating patterns AP1 may be spaced from each other in the first direction X at regular intervals. The second activating patterns AP2 may be spaced from each other in the first direction X at regular intervals. The first and second activating patterns AP1 and AP2 may be arranged in a two-dimensional way in the first direction X and the second direction Y crossing each other. That is, the first activating patterns AP1 and the second activating patterns AP2 may be respectively spaced from each other in the second direction Y to face each other.

The first activating pattern AP1 and the second activating pattern AP2 may be respectively made of a monocrystalline semiconductor material. For example, the first activating pattern AP1 and the second activating pattern AP2 may be respectively made of monocrystalline silicon, although embodiments are not limited thereto.

The first activating pattern AP1 and the second activating pattern AP2 may respectively have a length in the first direction X, may have a width in the second direction Y, and may have a height in the third direction Z. The first activating pattern AP1 and the second activating pattern AP2 may respectively have a substantially uniform width. That is, the first activating pattern AP1 and the second activating pattern AP2 may have substantially equivalent widths on first and second surfaces opposite each other in the third direction Z that is the vertical direction. Further, the width of the first activating pattern AP1 may be substantially equivalent to the width of the second activating pattern AP2. However, without being limited thereto, in several embodiments, regarding the first activating pattern AP1 and the second activating pattern AP2, first surfaces and second surfaces opposite each other in the third direction Z that is the vertical direction may have different widths. For example, the first activating pattern AP1 and the second activating pattern AP2 may have widths that increase in accordance with a distance from the bit line BL so the widths of the first surface and the second surface of the respective first activating pattern AP1 and the second activating pattern AP2 may become different.

As shown in FIG. 2, the first surfaces of the first and second activating patterns AP1 and AP2 may contact the polysilicon layer 161 of the bit line BL, and differing from what is shown in FIG. 2, they may contact the first metal layer 163 when the polysilicon layer 161 is omitted in one or more embodiments.

The width of the first activating pattern AP1 and the width of the second activating pattern AP2 may be several nanometers (nm) to several tens of nm. For example, the width of the first activating pattern AP1 and the width of the second activating pattern AP2 may be about 1 nm to about 30 nm, and more preferably, from about 1 nm to about 10 nm, but are not limited thereto.

The respective lengths of the first and second activating patterns AP1 and AP2 may be greater than the line width of the bit line BL. That is, the respective lengths of the first and second activating patterns AP1 and AP2 in the first direction X may be greater than the width of the bit line BL in the first direction X.

Although not shown, in some embodiments, the first and second activating patterns AP1 and AP2 may include a first dopant region near the bit line BL, a second dopant region near a contact pattern BC, and a channel region between the first and second dopant regions. The first and second dopant regions are regions where dopants are doped in the first and second activating patterns AP1 and AP2, and dopant concentration levels in the first and second activating patterns AP1 and AP2 may be greater than a dopant concentration level in the channel region. However, without being limited thereto, in several embodiments, the first activating pattern AP1 and the second activating pattern AP2 may not include at least one of the first dopant region and the second dopant region.

The first and second activating patterns AP1 and AP2 may be controlled by the first and second word lines WL1 and WL2, to be subsequently described, and the back gate electrodes BG, to be described, when the semiconductor device is operated. In one or more embodiments, each of the first and second activating patterns AP1 and AP2 is made of a monocrystalline semiconductor material so a leakage current characteristic of the semiconductor memory device may be improved.

The back gate electrodes BG may be disposed in the bit line BL and the shield pattern SP. The back gate electrodes BG may be between the first activating pattern AP1 and the second activating pattern AP2 that are adjacent each other in the second direction Y, and may cross the bit lines BL to extend in the first direction X. That is, the first activating pattern AP1 may be on a first side of each the back gate electrodes BG, and the second activating pattern AP2 may be on a second side of each the back gate electrodes BG, opposite the first side. The height of the back gate electrodes BG in the third direction Z may be less than the height of the first and second activating patterns AP1 and AP2 in the third direction Z.

The first activating pattern AP1 may be between the first word line WL1, to be subsequently described, and the back gate electrode BG. The second activating pattern AP2 may be between the second word line WL2, to be described, and the back gate electrode BG. A pair of the first word line WL1 and the second word line WL2 may be between the back gate electrodes BG disposed near in the second direction Y.

The back gate electrodes BG may include a conducting material. For example, the back gate electrodes BG may include at least one of doped polysilicon, a conductive metal nitride, a conductive metal silicon nitride, a metal carbonitride, a conductive metal silicide, a conductive metal oxide, a two-dimensional material, and a metal, although embodiments are not limited thereto.

The back gate electrodes BG may receive a negative voltage when the semiconductor device is operated, and they may increase a threshold voltage of the vertical channel transistor. That is, as the vertical channel transistor becomes fine, the threshold voltage may be reduced to prevent deterioration of the leakage current characteristic.

The semiconductor device may further include a first back gate separating pattern 111, a second back gate separating pattern 113, and a back gate insulation pattern 115.

The first back gate separating pattern 111 and the second back gate separating pattern 113 may be between the first and second activating patterns AP1 and AP2 disposed near each other in the second direction Y. The first back gate separating pattern 111 and the second back gate separating pattern 113 may extend in the first direction X to be parallel to the back gate electrodes BG. The first back gate separating pattern 111 may directly contact the first and second activating patterns AP1 and AP2. The second back gate separating pattern 113 may be spaced apart from the first and second activating patterns AP1 and AP2 with the first back gate separating pattern 111 therebetween.

Each of the back gate electrodes BG may include a first surface BG_S1 and a second surface BG_S2 opposite the first surface BG_S1 and spaced apart from each other in the third direction Z that is a vertical direction. The first surface BG_S1 of the back gate electrode BG may face the bit line BL and the shield pattern SP, and the second surface BG_S2 of the back gate electrode BG may face the first back gate separating pattern 111 and the second back gate separating pattern 113. That is, the first back gate separating pattern 111 and the second back gate separating pattern 113 may be disposed on the second surface BG_S2 of the back gate electrode BG.

The first back gate separating pattern 111 and the second back gate separating pattern 113 may include an insulating material. The first back gate separating pattern 111 and the second back gate separating pattern 113 may respectively include at least one of a silicon oxide layer, a silicon oxynitride layer, or a silicon nitride layer. For example, the first back gate separating pattern 111 may include a silicon oxide layer, and the second back gate separating pattern 113 may include at least one of a silicon oxynitride layer and a silicon nitride layer. However, the materials included by the first back gate separating pattern 111 and the second back gate separating pattern 113 are not limited thereto, and may be changeable in many ways.

The first back gate separating pattern 111 and the second back gate separating pattern 113 may be on a substantially same level, in the third direction Z relative to the upper surface of the substrate 200 as a base reference layer, as a gate capping pattern 175. The second back gate separating pattern 113 may include a same material as the gate capping pattern 175, although embodiments are not limited thereto.

The back gate insulation pattern 115 may be between the back gate electrode BG and the first activating pattern AP1 and between the back gate electrode BG and the second activating pattern AP2. The back gate insulation pattern 115 may be between the back gate electrode BG and a gate insulation pattern GOX to be described.

The back gate insulation pattern 115 may include vertical portions for covering respective sides of the back gate electrode BG and a horizontal portion for connecting the vertical portions. That is, the vertical portions of the back gate insulation pattern 115 may cover the respective sides of the back gate electrode BG, and the horizontal portion of the back gate insulation pattern 115 may cover the second surface BG_S2 of the back gate electrode BG. That is, the back gate insulation pattern 115 and the second back gate separating pattern 113 may be sequentially disposed, in the third direction Z, on the second surface BG_S2 of the back gate electrode BG.

The back gate insulation pattern 115 may include, for example, a silicon oxide layer, a silicon oxynitride layer, a high dielectric insulation layer having a greater dielectric constant than the silicon oxide layer, or combinations thereof.

The first back gate capping pattern BP1 and the second back gate capping pattern BP2 may be disposed between the bit line BL and the back gate electrode BG. That is, the first back gate capping pattern BP1 and the second back gate capping pattern BP2 may be sequentially disposed on the first surface BG_S1 of the back gate electrode BG.

The first back gate capping pattern BP1 may be between the first and second activating patterns AP1 and AP2 and the first and second word lines WL1 and WL2 to be described. The first back gate capping pattern BP1 may include a first surface facing the bit line BL and the shield pattern SP in the third direction Z that is a vertical direction and a second surface, opposite the first surface of the back gate capping pattern BP1, facing the back gate electrode BG, the first surface of the first back gate capping pattern BP1 may directly contact the bit line BL and the second back gate capping pattern BP2, and the second surface may directly contact the first surface BG_S1 of the back gate electrode BG. The respective surfaces of the first back gate capping pattern BP1 may be covered by the back gate insulation pattern 115.

As shown in FIG. 3 and FIG. 5, the back gate insulation pattern 115 and the first back gate capping pattern BP1 may define a gap region GR between the first and second word lines WL1 and WL2 facing each other in the second direction Y between the first activating patterns AP1 spaced from each other in the first direction X and between the second activating patterns AP2 spaced from each other in the first direction X. That is, the gap region GR defined by the back gate insulation pattern 115 and the first back gate capping pattern BP1 may not overlap the first and second activating patterns AP1 and AP2 in the second direction Y, and may at least partially overlap the first and second word lines WL1 and WL2 disposed between the first and second activating patterns AP1 and AP2 spaced in the first direction X, in the second direction Y.

As the back gate insulation pattern 115 and the first back gate capping pattern BP1 include the gap region GR, the respective cross-sectional thicknesses of the back gate insulation pattern 115 and the first back gate capping pattern BP1 in the gap region GR in the third direction Z may be different from the cross-sectional thicknesses of the back gate insulation pattern 115 and the first back gate capping pattern BP1 in a region that is exclusive of the gap region GR in the third direction Z. That is, as shown in FIG. 2, the cross-sectional thicknesses of the back gate insulation pattern 115 and the first back gate capping pattern BP1 not overlapping the first and second activating patterns AP1 and AP2 in the second direction Y, in the third direction Z, may be less than the cross-sectional thicknesses of the back gate insulation pattern 115 and the first back gate capping pattern BP1 overlapping the first and second activating patterns AP1 and AP2 in the second direction Y, in the third direction Z.

Here, the thickness of the back gate insulation pattern 115 in the third direction Z may represent a length of a vertical portion of the back gate insulation pattern 115 on a side of the back gate electrode BG and extending toward the substrate 200 in the third direction Z, and the thickness of the first back gate capping pattern BP1 may indicate a thickness of the first back gate capping pattern BP1 disposed on the second surface BG_S2 of the back gate electrode BG.

In detail, as shown in FIG. 3 and FIG. 5, the first back gate capping pattern BP1 may cover the second surface BG_S2 of the back gate electrode BG, and may define the gap region GR in the region of the back gate electrode BG not overlapping the first and second activating patterns AP1 and AP2 in the second direction Y.

The first back gate capping pattern BP1 may include a first portion BP1a, for covering the first surface BG_S1 of the back gate electrode BG, and second portions BP1b extending in the third direction Z toward the shield pattern SP from the first portion BP1a. The second portions BP1b of the first back gate capping pattern BP1 may be spaced apart from one another in the first direction X. The gap region GR of the first back gate capping pattern BP1 may be defined by the first portion BP1a of the first back gate capping pattern BP1 and the second portions BP1b neighboring each other.

Hence, the gap region GR of the first back gate capping pattern BP1 may be curved (e.g., dented) toward the back gate electrode BG from the shield pattern SP.

The cross-sectional thickness of the first portion BP1a of the first back gate capping pattern BP1 in the third direction Z may be less than the cross-sectional thickness of the second portion BP1b in the third direction Z.

The second back gate capping pattern BP2 may be on the first back gate capping pattern BP1. The second back gate capping pattern BP2 may be in the gap region GR of the first back gate capping pattern BP1. The second back gate capping pattern BP2 may at least partially fill the gap region GR of the first back gate capping pattern BP1.

As the second back gate capping pattern BP2 is in the gap region GR, the second portion BP1b of the first back gate capping pattern BP1 and the second back gate capping pattern BP2 may be alternately disposed in the first direction X. That is, the second back gate capping pattern BP2 may be between the second portion BP1b of the first back gate capping pattern BP1.

The second portion BP1b of the first back gate capping pattern BP1 may overlap the bit line BL in the third direction Z, and the second back gate capping pattern BP2 may overlap the line portions SP1 of the shield pattern SP in the third direction Z. The second portion BP1b of the first back gate capping pattern BP1 may directly contact the polysilicon layer 161 of the bit line BL, and the second back gate capping pattern BP2 may directly contact the spacer insulation layer 171.

The second back gate capping pattern BP2 may include a first surface disposed near the shield pattern SP in the third direction Z that is a vertical direction and a second surface disposed near the back gate electrode BG. The first surface of the second back gate capping pattern BP2 may be recessed by the spacer insulation layer 171. That is, the first surface of the second back gate capping pattern BP2 may be recessed along a contact side with the spacer insulation layer 171. In other words, the first surface of the second back gate capping pattern BP2 directly contacting the spacer insulation layer 171 may exhibit a curvature in a concave way toward the second surface of the second back gate capping pattern BP2. Hence, the second portion BP1b of the first back gate capping pattern BP1 directly contacting the polysilicon layer 161 of the bit line BL may be on a different level from the first surface of the second back gate capping pattern BP2 in the third direction Z.

The first back gate capping pattern BP1 and the second back gate capping pattern BP2 may include at least one of a silicon oxide, a silicon nitride, a silicon oxynitride, or a low dielectric (low-k) material with a lower dielectric constant than the silicon oxide such as SiBN, SiCN, SiOCH, and SiOC.

In several embodiments, the first back gate capping pattern BP1 and the second back gate capping pattern BP2 may include different materials. For example, the first back gate capping pattern BP1 may include a silicon oxide, and the second back gate capping pattern BP2 may include at least one of a silicon nitride, a silicon oxynitride, or a low dielectric constant (low-k) material with a lower dielectric constant than the silicon oxide, such as SiBN, SiCN, SiOCH, and SiOC, although embodiments are not limited thereto. However, this is an example, and the materials included by the first back gate capping pattern BP1 and the second back gate capping pattern BP2 are changeable in many ways.

The semiconductor device may further include an etching stopping pattern SL between the first back gate capping pattern BP1 and the second back gate capping pattern BP2.

The etching stopping pattern SL may be conformally disposed along an internal side of the gap region GR of the first back gate capping pattern BP1. The etching stopping pattern SL may be conformally disposed along the first back gate capping pattern BP1 in the gap region GR and the back gate insulation pattern 115. The etching stopping pattern SL may at least partially cover an internal side of the gap region GR of the first back gate capping pattern BP1. One side of the etching stopping pattern SL may directly contact the first back gate capping pattern BP1 and the back gate insulation pattern 115, and the other side of the etching stopping pattern SL may directly contact the second back gate capping pattern BP2.

In several embodiments, the etching stopping pattern SL may include the same material as the first back gate capping pattern BP1, and may include a different material from the second back gate capping pattern BP2. For example, the etching stopping pattern SL may include at least one of a silicon oxide or a low dielectric (low-k) material with a lower dielectric constant than the silicon oxide such as SiOCH or SiOC. However, this is an example, the material included by the etching stopping pattern SL may be changed in many ways.

The first word line WL1 and the second word line WL2 may be on the bit line BL and the shield pattern SP. The first word line WL1 and the second word line WL2 may respectively extend in the first direction X. The first word line WL1 and the second word line WL2 may be spaced apart from one another in the second direction Y, and may be alternately disposed in the second direction Y. The first activating patterns AP1 and the second activating patterns AP2 may be between the first word line WL1 and the second word line WL2 disposed near each other in the second direction Y.

In detail, as shown in FIG. 1 and FIG. 5, the first and second activating patterns AP1 and AP2 may respectively include first sides AP1_S1 and AP2_S1 and second sides AP1_S2 and AP2_S2 opposite each other in the second direction Y.

The respective first sides AP1_S1 and AP2_S1 of the first and second activating patterns AP1 and AP2 may face the back gate electrode BG, and the respective second sides AP1_S2 and AP2_S2 of the first and second activating patterns AP1 and AP2 may face the first word line WL1 and the second word line WL2. That is, the respective first sides AP1_S1 and AP2_S1 of the first and second activating patterns AP1 and AP2 may directly contact the back gate insulation pattern 115, and the respective second sides AP1_S2 and AP2_S2 of the first and second activating patterns AP1 and AP2 may directly contact the gate insulation pattern GOX.

In several embodiments, the respective first sides AP1_S1 and AP2_S1 of the first and second activating patterns AP1 and AP2 may have a straight line shape in a plan view, and the respective second sides AP1_S2 and AP2_S2 of the first and second activating patterns AP1 and AP2 may have a round curved shape. That is, the respective second sides AP1_S2 and AP2_S2 of the first and second activating patterns AP1 and AP2 may have a round curved shape to be near the back gate electrode BG at an end of the first direction X. In other words, third sides AP1_S3 and AP2_S3 and fourth sides AP1_S4 and AP2_S4 of the first and second activating patterns AP1 and AP2 that are vertical to the respective first sides AP1_S1 and AP2_S1 of the first and second activating patterns AP1 and AP2 and the second sides AP1_S2 and AP2_S2 of the first and second activating patterns AP1 and AP2 in a plan view and are spaced in the first direction X may be respectively connected to the second sides AP1_S2 and AP2_S2 of the first and second activating patterns AP1 and AP2 through a curved line. However, the planar shapes of the first sides AP1_S1 and AP2_S1 and the second sides AP1_S2 and AP2_S2 of the first and second activating patterns AP1 and AP2 are not limited thereto and may be modifiable in many ways.

In several embodiments, the respective first and second word lines WL1 and WL2 may, as shown in FIG. 5, include body portions WL1_B and WL2_B, extending in the first direction X, and protrusions WL1_P and WL2_P, extending in the second direction Y from the body portions WL1_B and WL2_B.

In detail, the first word line WL1 may include a first body portion WL1_B extending in the first direction X and a first protrusion WL1_P extending in the second direction Y from the first body portion WL1_B and disposed between the first activating patterns AP1 neighboring each other in the first direction X. The second word line WL2 may include a second body portion WL2_B extending in the first direction X and a second protrusion WL2_P extending in the second direction Y from the second body portion WL2_B and disposed between the second activating patterns AP2 neighboring each other in the first direction X.

Each of the respective first word line WL1 and the second word line WL2 may have a width in the second direction Y. The width of the first word line WL1 and the width of the second word line WL2 disposed in the bit line BL may be different from the width of the first word line WL1 and the width of the second word line WL2 disposed on the shield pattern SP. For example, regarding the respective first word line WL1 and the second word line WL2, the widths of the first and second word lines WL1 and WL2 in which the protrusions WL1_P and WL2_P are disposed in the second direction Y may be greater than the widths of the first and second word lines WL1 and WL2 in which the protrusions WL1_P and WL2_P are not disposed in the second direction Y. For example, the protrusions WL1_P and WL2_P of the first and second word lines WL1 and WL2 may be disposed on the shield pattern SP, and may be spaced in the second direction Y to face each other.

Hence, the respective first and second activating patterns AP1 and AP2 may be surrounded by the body portions WL1_B and WL2_B and the protrusions WL1_P and WL2_P of the first and second word lines WL1 and WL2. That is, the respective second sides AP1_S2 and AP2_S2 of the first and second activating patterns AP1 and AP2 may face the body portions WL1_B and WL2_B of the first and second word lines WL1 and WL2, and the respective third sides AP1_S3 and AP2_S3 and the fourth sides AP1_S4 and AP2_S4 of the first and second activating patterns AP1 and AP2 may face the protrusions WL1_P and WL2_P of the first and second word lines WL1 and WL2. As used herein, the term “surround” (or “surrounding” or like terms, such as “enclose”) is intended to broadly refer to an element, structure or layer that extends around, envelops, encircles, or encloses another element, structure or layer on all sides, although breaks or gaps may also be present.

In several embodiments, as shown in FIG. 5, ends of the protrusions WL1_P and WL2_P of the respective first and second word lines WL1 and WL2 may be disposed substantially in the same extending lines between regions between the first sides AP1_S1 and AP2_S1 and the second sides AP1_S2 and AP2_S2 of the first and second activating patterns AP1 and AP2 and in the first direction X in a plan view.

For example, the end of the first protrusion WL1_P of the first word line WL1 may be between the first side AP1_S1 and the second side AP1_S2 of the first activating pattern AP1. That is, the protrusion WL1_P of the first word line WL1 may extend in the second direction Y so that it may be between the first side AP1_S1 and the second side AP1_S2 of the first activating pattern AP1 from the first body portion WL1_B of the first word line WL1 in a plan view.

Hence, the first protrusion WL1_P of the first word line WL1 may overlap at least a portion of the first activating pattern AP1 in the first direction X in a plan view.

An arrangement relationship between the ends of the protrusions WL1_P and WL2_P of the respective first and second word lines WL1 and WL2 and the first sides AP1_S1 and AP2_S1 and the second sides AP1_S2 and AP2_S2 of the first and second activating patterns AP1 and AP2 in a plan view may not be limited thereto and may be modifiable in many ways.

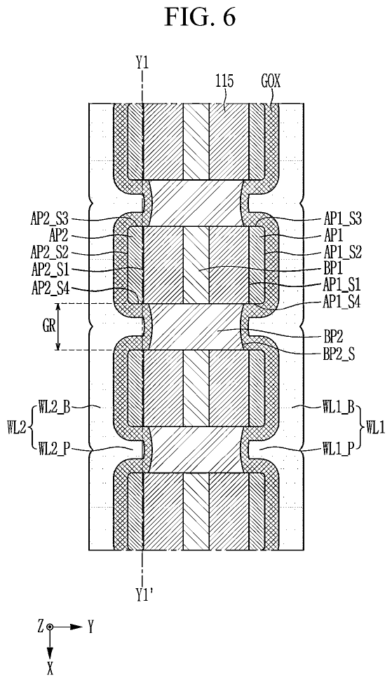

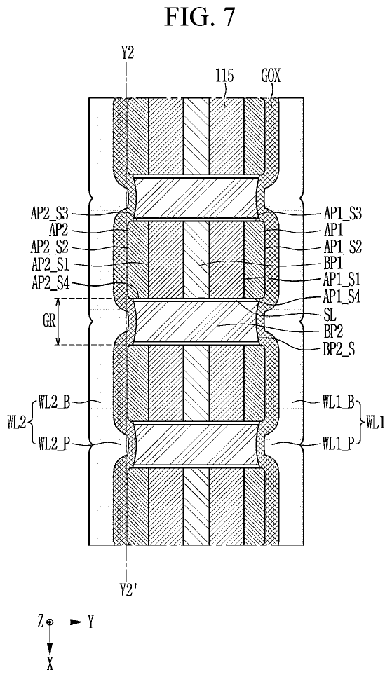

For example, as shown in FIG. 6 and FIG. 7, the end of the first protrusion WL1_P of the first word line WL1 may be disposed in the substantially same boundary line as the first side AP1_S1 or the second side AP1_S2 of the first activating pattern AP1 in a plan view.

In detail, in several embodiments, as shown in FIG. 6, the end of the protrusion WL1_P of the first word line WL1 may be in a virtual extension line Y1-Y1′ in the first direction X, on the first side AP1_S1 of the first activating pattern AP1. That is, the end of the first protrusion WL1_P of the first word line WL1 may extend in the second direction Y to reach the virtual extension line Y1-Y1′ on the first side AP1_S1 of the first activating pattern AP1 from the first body portion WL1_B of the first word line WL1 and may be on substantially the same boundary as the first side AP1_S1 of the first activating pattern AP1 in a plan view.

Hence, the first protrusion WL1_P of the first word line WL1 may completely overlap the first activating pattern AP1 in the first direction X in a plan view.

In one or more embodiments, as shown in FIG. 7, the end of the protrusion WL1_P of the first word line WL1 may be in the virtual extension line Y2-Y2′ in the first direction X, on the second side AP1_S2 of the first activating pattern AP1. That is, the end of the first protrusion WL1_P of the first word line WL1 may extend in the second direction Y to reach the virtual extension line Y2-Y2′ on the second side AP1_S2 of the first activating pattern AP1 from the first body portion WL1_B of the first word line WL1 in a plan view, and may be on substantially the same boundary as the second side AP1_S2 of the first activating pattern AP1.

Hence, the first protrusion WL1_P of the first word line WL1 may not overlap the first activating pattern AP1 in the first direction X in a plan view.

As described above, the arrangement relationship between the first protrusion WL1_P of the first word line WL1 and the first side AP1_S1 and the second side AP1_S2 of the first activating pattern AP1 and the corresponding overlapping relationship between the first protrusion WL1_P of the first word line WL1 and the first activating pattern AP1 may be changeable in many ways according to a pattern by which the second back gate capping pattern BP2 is etched in the process for forming the second back gate capping pattern BP2 in the gap region GR, and etching the second back gate capping pattern BP2.

The arrangement between the first word line WL1 and the first activating pattern AP1 has been described, and it may be similarly applied to the arrangement between the second word line WL2 and the second activating pattern AP2.

Further, the gap region GR of the first back gate capping pattern BP1 may be between the protrusions WL1_P and WL2_P of the first and second word lines WL1 and WL2. For example, the gap region GR of the first back gate capping pattern BP1 may be spaced apart from the first protrusion WL1_P of the first word line WL1 in the second direction Y and may be between the second protrusion WL2_P of the second word line WL2 facing the first protrusion WL1_P.

As the first and second protrusions WL1_P and WL2_P are on the shield pattern SP, the gap region GR of the first back gate capping pattern BP1 may at least partially overlap the shield pattern SP in the third direction Z that is a vertical direction.

The first word line WL1 and the second word line WL2 may be between the bit line BL and the contact pattern BC, and may extend in the third direction Z. Differing from what is shown in FIG. 2, in some embodiments, the respective first and second word lines WL1 and WL2 may have an L-shaped cross-section.

As shown in FIG. 2 and FIG. 4, each of the respective first and second word lines WL1 and WL2 may include a first surface WL_S1 and a second surface WL_S2 opposite each other in the third direction Z that is a vertical direction. The first surface WL_S1 of the respective first and second word lines WL1 and WL2 may face the bit line BL and the shield pattern SP, and the second surface WL_S2 may face the contact pattern BC and the gate capping pattern 175 to be described.

In one or more embodiments, the lengths of the first and second word lines WL1 and WL2 in the third direction Z may be greater than the length of the back gate electrode BG in the third direction Z. That is, the respective first surface WL_S1 and the second surface WL_S2 of the first and second word lines WL1 and WL2 may be on different levels from the first surface BG_S1 and the second surface BG_S2 of the back gate electrode BG.

In detail, the first surface WL_S1 of the respective first and second word lines WL1 and WL2 may be on a vertical level, relative to the upper surface of the substrate 200, that is lower than a vertical level of the first surface BG_S1 of the back gate electrode BG, and the second surface WL_S2 of the respective first and second word lines WL1 and WL2 may be on a vertical level, relative to the upper surface of the substrate 200, that is higher than the second surface BG_S2 of the back gate electrode BG. That is, the first surfaces WL_S1 of the first and second word lines WL1 and WL2 may be nearer the bit line BL and the shield pattern SP than the first surface BG_S1 of the back gate electrode BG, and the second surface WL_S2 of the respective first and second word lines WL1 and WL2 may be further spaced toward the third direction Z from the bit line BL and the shield pattern SP than the second surface BG_S2 of the back gate electrode BG.

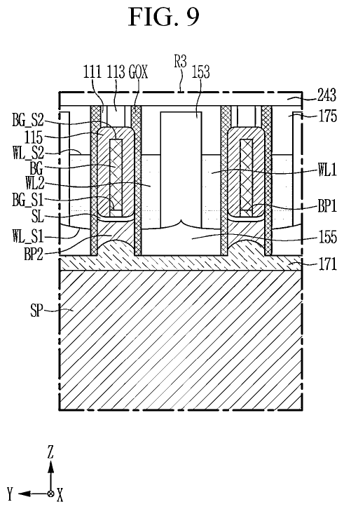

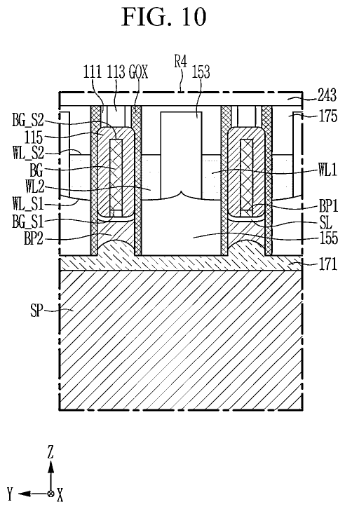

Hence, the back gate electrode BG may completely overlap the first and second word lines WL1 and WL2 in the second direction Y. However, the arrangement of the first surface WL_S1 and the second surface WL_S2 of the first and second word lines WL1 and WL2 and the first surface BG_S1 and the second surface BG_S2 of the back gate electrode BG, relative to one another, may be modifiable in many ways. A detailed description thereof will be described later with reference to FIG. 9 and FIG. 10.

In one or more embodiments, the lengths of the first and second word lines WL1 and WL2 in the third direction Z may be less than the lengths of the first and second activating patterns AP1 and AP2 in the third direction Z.

Each of the first and second word lines WL1 and WL2 may include a conducting material; for example, they may include at least one of doped polysilicon, a conductive metal nitride, a conductive metal silicon nitride, a metal carbonitride, a conductive metal silicide, a conductive metal oxide, a two-dimensional material, and a metal, although embodiments are not limited thereto.

The semiconductor device may further include a gate insulation pattern GOX, a first gate separating pattern 153, a second gate separating pattern 155, and the gate capping pattern 175.

The gate insulation pattern GOX may be between the first word line WL1 and the first activating pattern AP1 and between the second word line WL2 and the second activating patterns AP2. The gate insulation pattern GOX may be between the first word line WL1 and the back gate insulation pattern 115 and between the second word line WL2 and the back gate insulation pattern 115. The gate insulation pattern GOX may extend in the first direction X to be parallel to the first and second word lines WL1 and WL2.

In detail, referring to FIG. 2 and FIG. 5, the gate insulation pattern GOX may extend along the second side AP1_S2, the third side AP1_S3, and the fourth side AP1_S4 of the first activating pattern AP1, and may extend along the second side AP2_S2, the third side AP2_S3, and the fourth side AP2_S4 of the second activating pattern AP2. The gate insulation pattern GOX may conformally extend along a side profile of the first and second activating patterns AP1 and AP2.

For example, in one or more embodiments, as described above, when the second sides AP1_S2 and AP2_S2 of the first and second activating patterns AP1 and AP2 have round curved surfaces, the gate insulation pattern GOX extending along the second sides AP1_S2 and AP2_S2 of the first and second activating patterns AP1 and AP2 may have a round curved surface.

Further, the gate insulation pattern GOX may be disposed between the first word line WL1 and the second back gate capping pattern BP2 and between the second word line WL2 and the second back gate capping pattern BP2. That is, the gate insulation pattern GOX may conformally extend along the side BP2_S of the second back gate capping pattern BP2 facing the first and second word lines WL1 and WL2. The gate insulation pattern GOX may extend in the first direction X to be parallel to the side BP2_S of the second back gate capping pattern BP2.

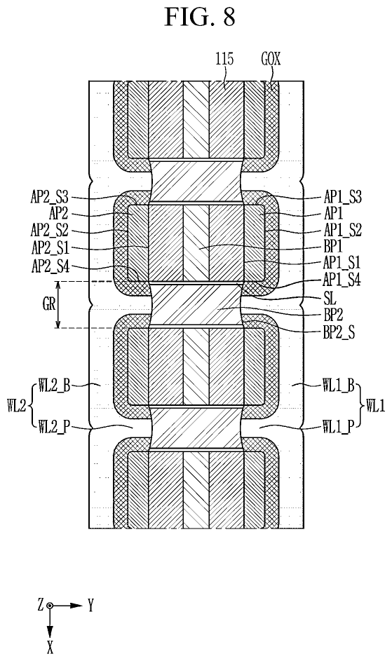

As shown in FIG. 8, in one or more embodiments, the gate insulation pattern GOX may be between the first word line WL1 and the first activating pattern AP1 and between the second word line WL2 and the second activating patterns AP2, and the gate insulation pattern GOX may not be between the protrusions WL1_P and WL2_P of the first and second word lines WL1 and WL2 and the side BP2_S of the second back gate capping pattern BP2. That is, the gate insulation pattern GOX may extend along the second sides AP1_S2 and AP2_S2, the third sides AP1_S3 and AP2_S3, and the fourth sides AP1_S4 and AP2_S4 of the first and second activating patterns AP1 and AP2, and may be spaced apart from one another in the first direction X.

As the first and second activating patterns AP1 and AP2 and the second back gate capping pattern BP2 include different materials, the gate insulation pattern GOX may be formed on the second sides AP1_S2 and AP2_S2, the third sides AP1_S3 and AP2_S3, and the fourth sides AP1_S4 and AP2_S4 of the first and second activating patterns AP1 and AP2 in the process for forming the gate insulation pattern GOX.

As shown in FIG. 5, the gate insulation pattern GOX extending along the second sides AP1_S2 and AP2_S2, the third sides AP1_S3 and AP2_S3, and the fourth sides AP1_S4 and AP2_S4 of the first and second activating patterns AP1 and AP2 may have a first width W1 in the second direction Y, and the gate insulation pattern GOX extending along the side BP2_S of the second back gate capping pattern BP2 may have a second width W2 in the second direction Y.

In one or more embodiments, the first width W1 of the gate insulation pattern GOX on the second sides AP1_S2 and AP2_S2, the third sides AP1_S3 and AP2_S3, and the fourth sides AP1_S4 and AP2_S4 of the first and second activating patterns AP1 and AP2 may be different from the second width W2 of the gate insulation pattern GOX on the side BP2_S of the second back gate capping pattern BP2. For example, in some embodiments the first width W1 may be greater than the second width W2. However, without being limited thereto, the first width W1 may be substantially equal to the second width W2.

As the first and second activating patterns AP1 and AP2 and the second back gate capping pattern BP2 include different materials, the thickness or width of the gate insulation pattern GOX formed on the second sides AP1_S2 and AP2_S2, the third sides AP1_S3 and AP2_S3, and the fourth sides AP1_S4 and AP2_S4 of the first and second activating patterns AP1 and AP2 may be different from the thickness or width of the gate insulation pattern GOX formed on the side BP2_S of the second back gate capping pattern BP2 in the process for forming the gate insulation pattern GOX.

The gate insulation pattern GOX may be made of a silicon oxide layer, a silicon oxynitride layer, a high dielectric layer with a greater dielectric constant than the silicon oxide layer, or combinations thereof. The high dielectric layer may be made of a metal oxide or a metal oxynitride. For example, the high dielectric layer usable as the gate insulation pattern GOX may be made of HfO₂, HfSiO, HfSiON, HfTaO, HfTiO, HfZrO, ZrO₂, Al₂O₃, or combinations thereof, but is not limited thereto.

The first gate separating pattern 153 may be between the first and second word lines WL1 and WL2. The first gate separating pattern 153 may directly contact the first and second word lines WL1 and WL2. The height of the first gate separating pattern 153, in the third direction Z relative to the upper surface of the substrate 200 as a base reference layer, may be greater than the height of the first and second word lines WL1 and WL2 in the third direction Z. The first and second word lines WL1 and WL2 may be separated from each other by the first gate separating pattern 153 disposed therebetween.

The second gate separating pattern 155 may be on the first and second word lines WL1 and WL2 and the first gate separating pattern 153. The second gate separating pattern 155 may be between the spacer insulation layer 171 and the first and second word lines WL1 and WL2 and between the spacer insulation layer 171 and the first gate separating pattern 153. The second gate separating pattern 155 may directly contact the first surface WL_S1 of the first and second word lines WL1 and WL2 and the first gate separating pattern 153. The second gate separating pattern 155 may be disposed between the bit line BL and the first and second word lines WL1 and WL2, and may directly contact the bit line BL.

The gate insulation pattern GOX may be between the second back gate capping pattern BP2 and the second gate separating pattern 155. The gate insulation pattern GOX may be between the first and second activating patterns AP1 and AP2 and the second gate separating pattern 155. The second gate separating pattern 155 may directly contact the gate insulation pattern GOX.

In one or more embodiments, the first gate separating pattern 153 and the second gate separating pattern 155 may respectively include an insulating material. For example, the first gate separating pattern 153 may include a silicon oxide, and the second gate separating pattern 155 may include a silicon nitride.

The gate capping pattern 175 may be between the first and second word lines WL1 and WL2 and a contact interlayer insulating layer 243 to be described. The gate capping pattern 175 may be on the second surface WL_S2 of the first and second word lines WL1 and WL2 and the first gate separating pattern 153. The gate capping pattern 175 may directly contact the first and second word lines WL1 and WL2 and the first gate separating pattern 153.

Further, the gate capping pattern 175 may be between the first and second word lines WL1 and WL2 and the contact pattern BC, and may directly contact at least a portion of the contact pattern BC.

The gate capping pattern 175 may be on substantially the same vertical level as the first back gate separating pattern 111, the second back gate separating pattern 113, and the gate insulation pattern GOX.

In one or more embodiments, the gate capping pattern 175 may include an insulating material. For example, the gate capping pattern 175 may include a silicon nitride.

Although not shown in FIG. 2 and FIG. 4, in one or more embodiments, at least one or more etch stopping layers (not shown) including an insulating material may be further included on the first back gate separating pattern 111, the second back gate separating pattern 113, and the gate insulation pattern GOX.

The semiconductor device may further include a contact interlayer insulating layer 243, a pad separating insulation pattern 245, a contact etch stopping layer 247, contact patterns BC, landing pads LP, and data storage patterns DSP.

The contact patterns BC may penetrate (i.e., extend into and/or through) the contact interlayer insulating layer 243. The contact patterns BC may be respectively connected to the first and second activating patterns AP1 and AP2. The contact patterns BC disposed near each other may be separated from each other by the contact interlayer insulating layer 243.

The respective contact patterns BC may have various shapes such as a circular shape, an oval shape, a rectangular shape, a square shape, a rhombus shape, and a hexagonal shape in a plan view, although embodiments are not limited thereto.

The contact pattern BC may include a conducting material. For example, it may include at least one of doped polysilicon, a conductive metal nitride, a conductive metal silicon nitride, a metal carbonitride, a conductive metal silicide, a conductive metal oxide, a two-dimensional material, and a metal, although embodiments are not limited thereto.

The landing pads LP may be disposed on the contact pattern BC. The landing pads LP may have various shapes such as a circular shape, an oval shape, a rectangular shape, a square shape, a rhombus shape, and a hexagonal shape in a plan view, although embodiments are not limited thereto.

The pad separating insulation pattern 245 may be on the contact interlayer insulating layer 243. The pad separating insulation patterns 245 may be between the landing pads LP. The landing pads LP may be arranged in a matrix pattern in the first direction X and the second direction Y in a plan view. An upper surface of the landing pad LP may form a substantially coplanar shape with an upper surface of the pad separating insulation pattern 245 in the third direction Z.

The landing pad LP may include a conducting material, for example, it may include at least one of doped polysilicon, a conductive metal nitride, a conductive metal silicon nitride, a metal carbonitride, a conductive metal silicide, a conductive metal oxide, a two-dimensional material, and a metal, although embodiments are not limited thereto.

The data storage patterns DSP may be disposed on the landing pads LP. The data storage patterns DSP may be respectively connected to the first and second activating patterns AP1 and AP2.

The data storage patterns DSP may, as shown in FIG. 1, be arranged in a matrix pattern in the first direction X and the second direction Y. The data storage patterns DSP may completely or partly overlap the landing pads LP in the third direction Z. The data storage patterns DSP may contact the entire upper surfaces or a portion of the landing pads LP.

For example, the data storage patterns DSP may be a capacitor. The data storage patterns DSP may include a capacitor dielectric layer 253 disposed between storage electrodes 251 and a plate electrode 255. In this case, the storage electrode 251 may contact the landing pad LP.

The storage electrode 251 may have various shapes such as a circular shape, an oval shape, a rectangular shape, a square shape, a rhombus shape, and a hexagonal shape in a plan view, although embodiments are not limited thereto.

The data storage patterns DSP may contact the entire upper surfaces or a portion of the landing pads LP. The storage electrodes 251 may penetrate (i.e., extend at least partially into and/or through) the contact etch stopping layer 247. The contact etch stopping layer 247 may include an insulating material.

Differing from this, the data storage patterns DSP may be variable resistance patterns that may be switched to two resistance states by an electrical pulse applied to a memory element. For example, the data storage patterns DSP may include a phase-change material of which a crystalline state is changed according to a current amount, perovskite compounds, transition metal oxides, magnetic materials, ferromagnetic materials, or antiferromagnetic materials, although embodiments are not limited thereto.

Although not shown, a memory cell contact plug connected to the plate electrode 255 may be disposed on the data storage patterns DSP.

According to the semiconductor device, etc. That is, as the second back gate capping pattern BP2 is filled in the gap region GR of the first back gate capping pattern BP1 as described above, the thickness of the insulation pattern on the back gate electrode BG may be maintained at more than a predetermined level, thereby preventing the back gate electrode BG from being damaged in the subsequent process and improving productivity and reliability of the semiconductor device. The term “exposure” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

In the process for patterning the second back gate capping pattern BP2, as the second back gate capping pattern BP2 is patterned with various types of patterns, the word lines WL1, and WL2 may be disposed to have various shapes.

Hereinafter, a semiconductor device according to various embodiments will now be described with reference to FIG. 9 to FIG. 17.

In the following embodiment, the same configurations as the above-described embodiments will use the same reference numerals, the repeated descriptions will be omitted or simplified, and the differences will be mainly described.

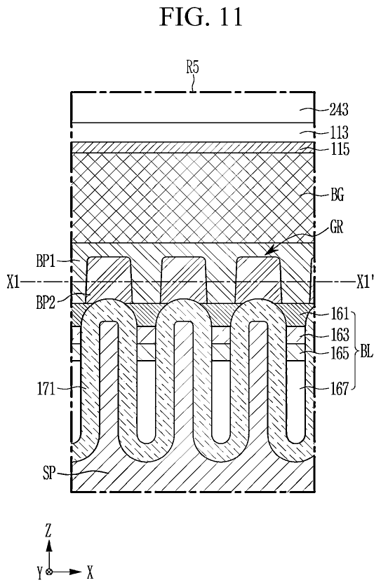

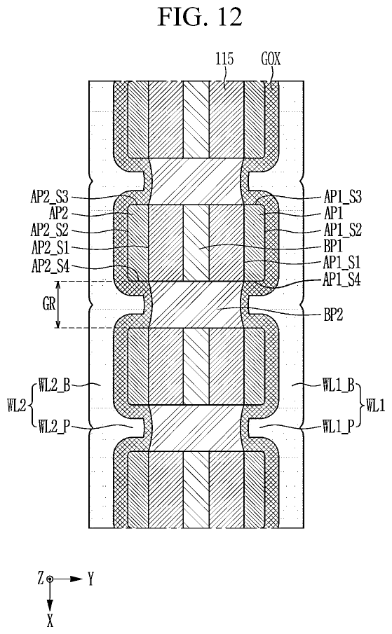

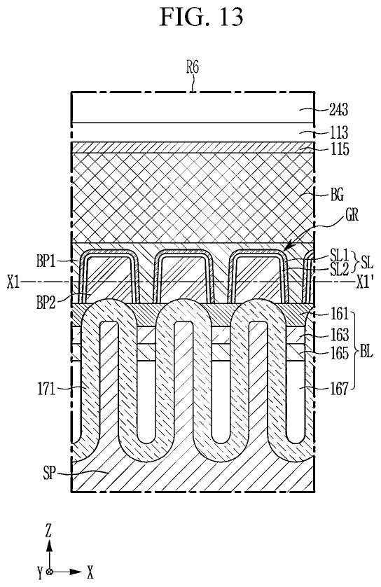

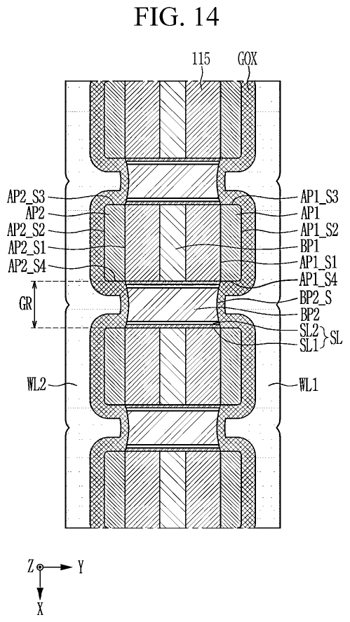

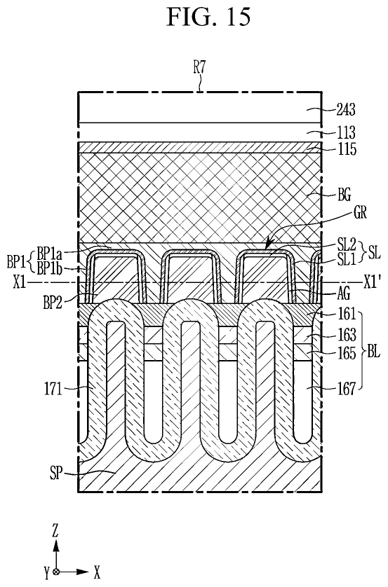

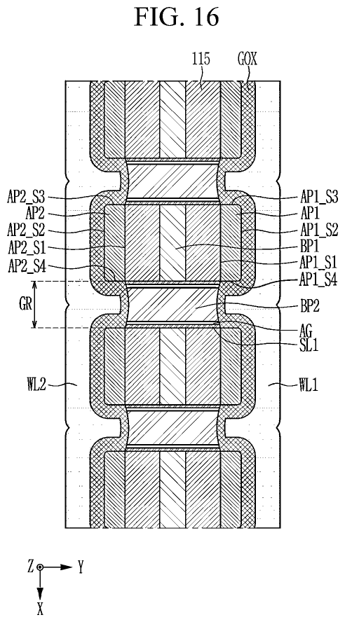

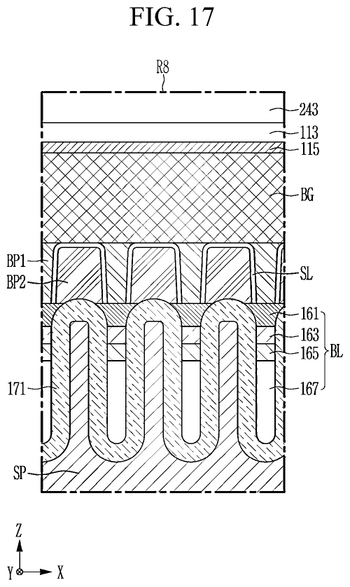

FIG. 9 to FIG. 11, FIG. 13, FIG. 15, and FIG. 17 show partially enlarged views of cross-sections of a semiconductor device according to one or more embodiments. FIG. 12 shows a top plan view of a semiconductor device corresponding to a level of a line X1-X1′ of FIG. 11. FIG. 14 shows a top plan view of a semiconductor device corresponding to a level of a line X1-X1′ of FIG. 13. FIG. 16 shows a top plan view of a semiconductor device corresponding to a level of a line X1-X1′ of FIG. 15.

In detail, FIG. 9 and FIG. 10 show a region R3 and a region R4, respectively, corresponding to alternative embodiments of the region R2 shown in FIG. 4. FIG. 11, FIG. 13, FIG. 15, and FIG. 17 show a region R5 to a region R8, respectively, corresponding to alternative embodiments of the region R1 shown in FIG. 3.

According to the embodiment shown in FIG. 9, differing from the embodiment described with reference to FIG. 4, one difference is in that the second surface WL_S2 of the first and second word lines WL1 and WL2 is on a lower level than the second surface BG_S2 of the back gate electrode BG in the third direction Z, relative to the upper surface of the substrate 200 as a base reference layer. That is, the second surface WL_S2 of the first and second word lines WL1 and WL2 may be nearer to the shield pattern SP than the second surface BG_S2 of the back gate electrode BG. In other words, the second surface BG_S2 of the back gate electrode BG may be between the first surface WL_S1 and the second surface WL_S2 of the first and second word lines WL1 and WL2.

In addition, compared to the embodiment shown in FIG. 4, the gate capping pattern 175 on the first and second word lines WL1 and WL2 may further extend toward the shield pattern SP in the third direction Z.

Hence, an end of the gate capping pattern 175 directly contacting the first and second word lines WL1 and WL2 may be on a lower level than the second surface BG_S2 of the back gate electrode BG in the third direction Z. That is, the end of the gate capping pattern 175 directly contacting the first and second word lines WL1 and WL2 may be nearer to the shield pattern SP than the second surface BG_S2 of the back gate electrode BG.

According to the embodiment described with reference to FIG. 10, differing from the embodiment shown in FIG. 4, one difference is in that the first surface WL_S1 of the first and second word lines WL1 and WL2 is on a higher level than the first surface BG_S1 of the back gate electrode BG in the third direction Z, and the second surface WL_S2 of the first and second word lines WL1 and WL2 is on a lower level than the second surface BG_S2 of the back gate electrode BG in the third direction Z. That is, the first surface WL_S1 of the first and second word lines WL1 and WL2 may be further spaced from the shield pattern SP in the third direction Z than the first surface BG_S1 of the back gate electrode BG. In other words, the first surface WL_S1 of the first and second word lines WL1 and WL2 may be between the first surface BG_S1 and the second surface BG_S2 of the back gate electrode BG. Further, the second surface WL_S2 of the first and second word lines WL1 and WL2 may be nearer to the shield pattern SP than the second surface BG_S2 of the back gate electrode BG.

Hence, an end of the second gate separating pattern 155 directly contacting the first and second word lines WL1 and WL2 may be on a higher level than the first surface BG_S1 of the back gate electrode BG in the third direction Z. That is, the end of the second gate separating pattern 155 directly contacting the first and second word lines WL1 and WL2 may be further spaced from the shield pattern SP in the third direction Z than the first surface BG_S1 of the back gate electrode BG.

In one or more embodiments, differing from what is shown in FIG. 9 and FIG. 10, at least one of the first surface WL_S1 and the second surface WL_S2 of the first and second word lines WL1 and WL2 may be on substantially the same level as the first surface BG_S1 and the second surface BG_S2 of the back gate electrode BG in the third direction Z; that is, at least one of the first surface WL_S1 and the second surface WL_S2 of the first and second word lines WL1 and WL2 may be coplanar with the first surface BG_S1 and the second surface BG_S2 of the back gate electrode BG.

For example, the first surface WL_S1 of the first and second word lines WL1 and WL2 may be on substantially the same level as the first surface BG_S1 of the back gate electrode BG in the third direction Z, or the second surface WL_S2 of the first and second word lines WL1 and WL2 may be on substantially the same level as the second surface BG_S2 of the back gate electrode BG in the third direction Z. For another example, the first surface WL_S1 and the second surface WL_S2 of the first and second word lines WL1 and WL2 may be on substantially the same level as the first surface BG_S1 and the second surface BG_S2 of the back gate electrode BG in the third direction Z.

The semiconductor device according to the embodiments described in conjunction with FIG. 9 and FIG. 10 may have substantially the same effect as the semiconductor device according to the embodiments described with reference to FIG. 1 to FIG. 8.

Further, in a like case of the semiconductor device according to embodiments shown in FIG. 9 and FIG. 10, as the first and second back gate capping patterns BP1 and BP2 are disposed on the back gate electrode BG, the back gate electrode BG may be prevented from being damaged and the first and second word lines WL1 and WL2 having various arrangement relationships with the back gate electrode BG may be formed in the process for forming the first and second word lines WL1 and WL2.

According to the embodiments shown in FIG. 11 and FIG. 12, differing from the embodiments shown in FIG. 3 and FIG. 5, one difference is in that the first back gate capping pattern BP1 and the second back gate capping pattern BP2 include the same material, and the etching stopping pattern SL between the first back gate capping pattern BP1 and the second back gate capping pattern BP2 is omitted.

In detail, referring to FIG. 11 and FIG. 12, the first back gate capping pattern BP1 and the second back gate capping pattern BP2 may include the same material. For example, the first back gate capping pattern BP1 and the second back gate capping pattern BP2 may include at least one of a silicon oxide or a low dielectric (low-k) material with a lower dielectric constant than the silicon oxide such as SiOCH or SiOC. However, this is an example, and the material included by the first back gate capping pattern BP1 and the second back gate capping pattern BP2 may be changeable in many ways.

Further, as the etching stopping pattern SL between the first back gate capping pattern BP1 and the second back gate capping pattern BP2 is omitted, the second back gate capping pattern BP2 may be in the gap region GR of the first back gate capping pattern BP1 and may directly contact the first back gate capping pattern BP1.

FIG. 11 shows that there is a boundary between the first back gate capping pattern BP1 and the second back gate capping pattern BP2, but as the first back gate capping pattern BP1 and the second back gate capping pattern BP2 include the same material, the boundary between the first back gate capping pattern BP1 and the second back gate capping pattern BP2 may not be distinguished.

According to the embodiments shown in FIG. 13 and FIG. 14, differing from the embodiments shown in FIG. 3 and FIG. 5, one difference is in that the etching stopping pattern SL between the first back gate capping pattern BP1 and the second back gate capping pattern BP2 is configured having multiple layers.

In detail, referring to FIG. 13 and FIG. 14, the etching stopping pattern SL between the first back gate capping pattern BP1 and the second back gate capping pattern BP2 may include a first etching stopping pattern SL1 and a second etching stopping pattern SL2 sequentially disposed in the gap region GR of the first back gate capping pattern BP1.

The first etching stopping pattern SL1 conformally may be disposed along an internal side of the gap region GR of the first back gate capping pattern BP1. The second etching stopping pattern SL2 may be disposed on the first etching stopping pattern SL1, and may be conformally disposed along a surface of the first etching stopping pattern SL1. Hence, the first etching stopping pattern SL1 may directly contact the first back gate capping pattern BP1, and the second etching stopping pattern SL2 may directly contact the second back gate capping pattern BP2.

In the present embodiment, the first etching stopping pattern SL1 and the second etching stopping pattern SL2 may include different materials. For example, the first etching stopping pattern SL1 may include a silicon oxide or at least one low dielectric constant (low-k) material with a lower dielectric constant than the silicon oxide such as SiOCH or SiOC, and the second etching stopping pattern SL2 may include a silicon nitride, a silicon oxynitride, or a low dielectric constant (low-k) material with a lower dielectric constant than silicon oxide such as SiBN or SiCN.

For another example, the first etching stopping pattern SL1 may include the same material as the first back gate capping pattern BP1, and the second etching stopping pattern SL2 may include the same material as the second back gate capping pattern BP2. However, the material included by the first etching stopping pattern SL1 and the second etching stopping pattern SL2 is not limited thereto, and in several embodiments, the first etching stopping pattern SL1 and the second etching stopping pattern SL2 may include the same material.

FIG. 13 and FIG. 14 show that the etching stopping pattern SL is configured with the first etching stopping pattern SL1 and the second etching stopping pattern SL2, and the number of layers or films configuring the etching stopping pattern SL is not limited thereto. For example, the etching stopping pattern SL may be configured with three or more layers, and another layer may be further disposed in at least one of between the first etching stopping pattern SL1 and the second etching stopping pattern SL2, between the first back gate capping pattern BP1 and the first etching stopping pattern SL1, and between the second etching stopping pattern SL and the second back gate capping pattern BP2.

Regarding the semiconductor device according to the embodiment shown in FIG. 13 and FIG. 14, as the etching stopping pattern SL between the first back gate capping pattern BP1 and the second back gate capping pattern BP2 are configured with insulation layers having different types of etching selectivity, it may be prevented to over-etch the first back gate capping pattern BP1 and expose the back gate electrode BG in the subsequent process.

According to the embodiments shown in FIG. 15 and FIG. 16, differing from the embodiments shown in FIG. 13 and FIG. 14, one difference is in that an air gap AG is further included.

In detail, referring to FIG. 15 and FIG. 16, the first etching stopping pattern SL1 may be conformally disposed along an internal side of the gap region GR of the first back gate capping pattern BP1.

The second etching stopping pattern SL2 may be disposed on the first portion BP1a of the first back gate capping pattern BP1, may be between the first etching stopping pattern SL1 and the second back gate capping pattern BP2, and may extend in the first direction X.

The air gap AG may be disposed on the second portion BP1b of the first back gate capping pattern BP1, and may be between the first etching stopping pattern SL1 and the second back gate capping pattern BP2. The air gap AG may be on respective sides of the second back gate capping pattern BP2, and may extend in the third direction Z to the back gate electrode BG from the bit line BL. The air gap AG may be spaced in the first direction X with the second etching stopping pattern SL2 and the second back gate capping pattern BP2 therebetween. However, the position and the number of the air gaps AG are not limited thereto and may be changeable in many ways.

For example, at least a portion of the first etching stopping pattern SL1 may include the air gap AG. For another example, when other layers in addition to the first etching stopping pattern SL1 and the second etching stopping pattern SL2 are between the first back gate capping pattern BP1 and the second back gate capping pattern BP2, at least some of the other layers may include the air gap AG.

The semiconductor device according to the embodiments shown in FIG. 15 and FIG. 16 may have substantially the same effect as the semiconductor device according to the embodiments shown in FIG. 13 and FIG. 14. Further, the semiconductor device according to the present embodiment may increase reliability of the semiconductor device as the air gap AG with an excellent insulating characteristic is included between the bit line BL and the back gate electrode BG.

According to the embodiment shown in FIG. 17, differing from the embodiments shown in FIG. 3 and FIG. 5, one difference is in that the shape of the first back gate capping pattern BP1 and the arrangement between the first back gate capping pattern BP1 and the second back gate capping pattern BP2 are changed.

In detail, referring to FIG. 17, the first back gate capping pattern BP1 may be on the first surface BG_S1 of the back gate electrode BG. The first back gate capping pattern BP1 may extend in the third direction Z toward the bit line BL from the first surface BG_S1 of the back gate electrode BG, and the first back gate capping pattern BP1 may be spaced in the first direction X.

The second back gate capping pattern BP2 may extend in the third direction Z toward the bit line BL from the first surface BG_S1 of the back gate electrode BG, and may be between the first back gate capping pattern BP1 neighboring each other in the first direction X. Hence, the first back gate capping pattern BP1 and the second back gate capping pattern BP2 may be alternately arranged in the first direction X on the first surface BG_S1 of the back gate electrode BG.

The etching stopping pattern SL may be between the first back gate capping pattern BP1 and the second back gate capping pattern BP2 and between the back gate electrode BG and the second back gate capping pattern BP2. That is, the etching stopping pattern SL may directly contact the first surface BG_S1 of the back gate electrode BG, may extend in the first direction X, may directly contact the first back gate capping pattern BP1 and the second back gate capping pattern BP2, and may extend in the third direction Z between the first back gate capping pattern BP1 and the second back gate capping pattern BP2.

The semiconductor device according to the embodiment shown in FIG. 17 may have substantially the same effect as the semiconductor device according to the embodiment shown in FIG. 3.

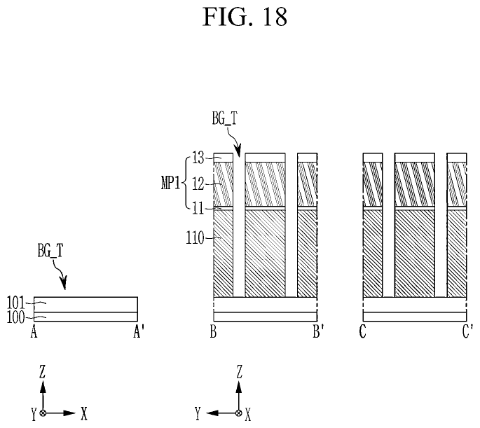

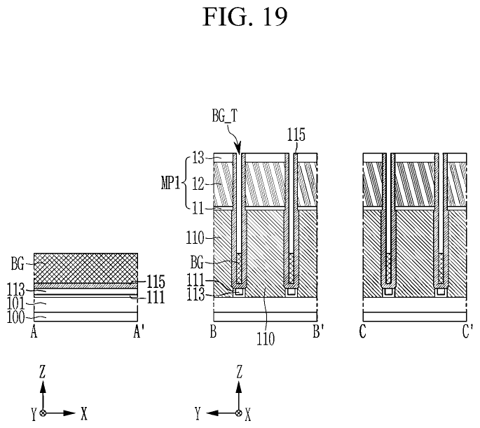

A method for manufacturing a semiconductor device will now be described with reference to FIG. 18 to FIG. 33. In the following embodiment, the same configurations as the above-described embodiments will use the same reference numerals, the repeated descriptions will be omitted or simplified, and the differences will be mainly described.

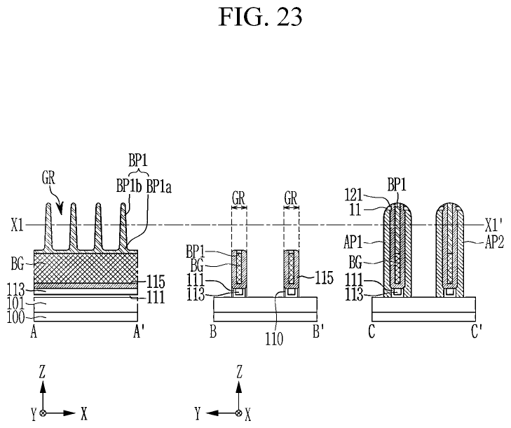

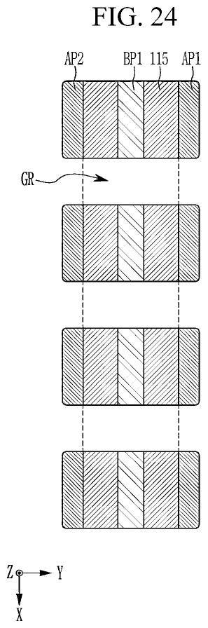

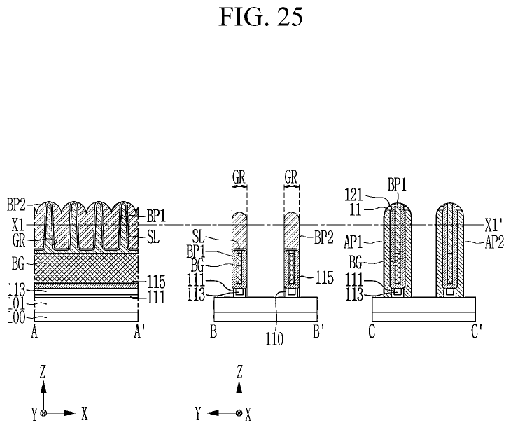

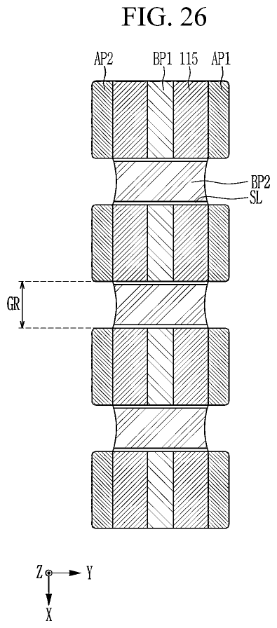

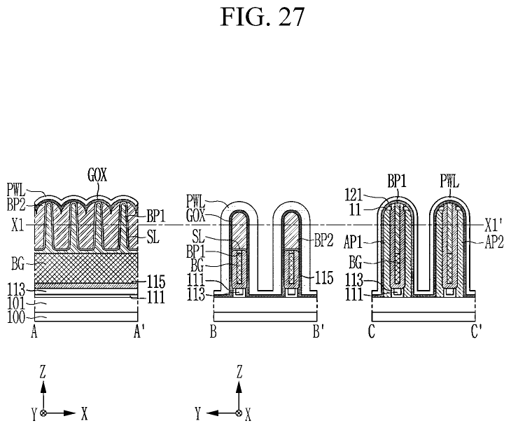

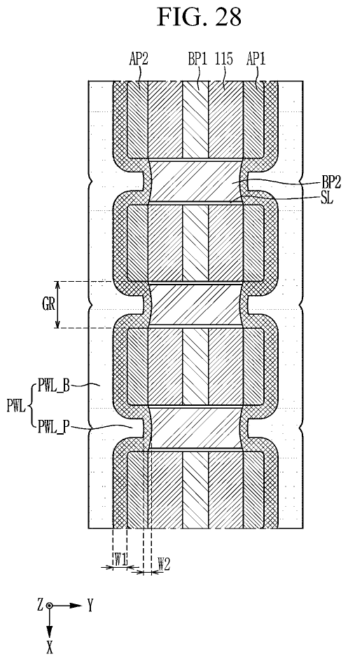

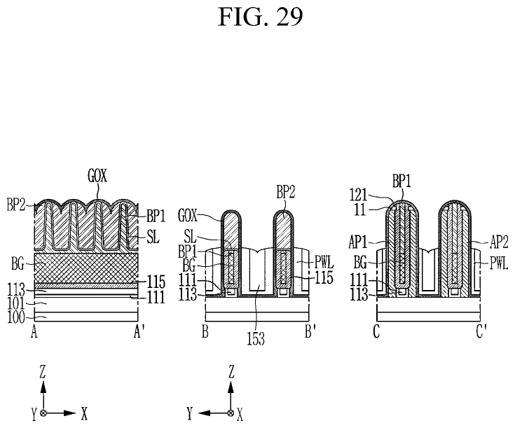

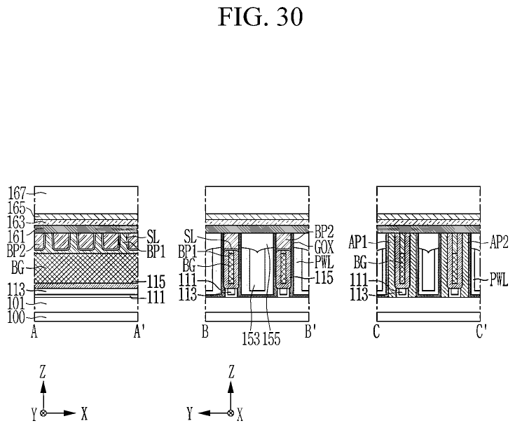

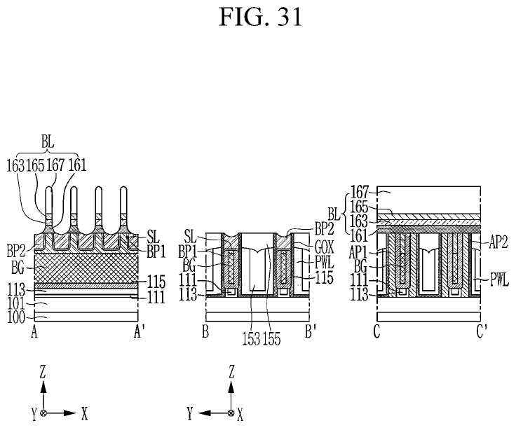

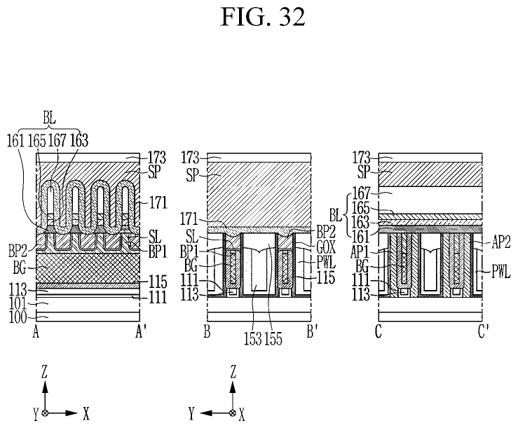

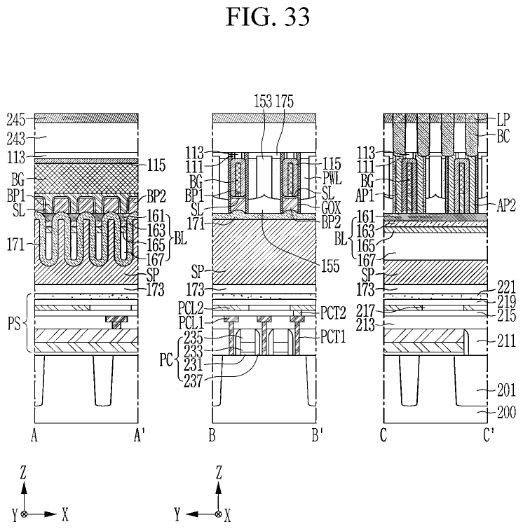

FIG. 18 to FIG. 23, FIG. 25, FIG. 27, and FIG. 29 to FIG. 33 show cross-sectional views of intermediate processes in an example method for manufacturing a semiconductor device according to one or more embodiments. FIG. 24 shows a top plan view of a semiconductor device corresponding to a level of a line X1-X1′ shown in FIG. 23. FIG. 26 shows a top plan view of a semiconductor device corresponding to a level of a line X1-X1′ shown in FIG. 25. FIG. 28 shows a top plan view of a semiconductor device corresponding to a level of a line X1-X1′ shown in FIG. 27.

In detail, FIG. 18 to FIG. 23, FIG. 25, FIG. 27, and FIG. 29 to FIG. 33 show cross-sectional views with respect to lines A-A′, B-B′, and C-C′ of FIG. 1.

Referring to FIG. 18 together with FIG. 1, a first substrate structure including a sub-substrate 100, a fill insulation layer 101, and an active layer 110 may be provided.

The sub-substrate 100 may, for example, be a silicon substrate, a germanium substrate, and/or a silicon-germanium substrate, although embodiments are not limited thereto.

The fill insulation layer 101 may comprise a buried oxide (BOX) layer formed, for example, by a separation by implanted oxygen (SIMOX) method or a bonding and layer transfer method. However, without being limited thereto, the fill insulation layer 101 may be made by a chemical vapor deposition (CVD) method.

The fill insulation layer 101 may, for example, include a silicon oxide layer, a silicon nitride layer, a silicon oxynitride layer, and/or a low dielectric layer, although embodiments are not limited thereto.

The active layer 110 may comprise a monocrystalline semiconductor material. The active layer may, for example, be a monocrystalline silicon substrate, a germanium substrate, and/or a silicon-germanium substrate, although embodiments are not limited thereto. The active layer 110 may have a first surface and a second surface opposite the first surface in the third direction Z that is a vertical direction, and the first surface may contact the fill insulation layer 101.

The first mask pattern MP1 may be formed on the active layer 110. The first mask pattern MP1 may include a first mask layer 11, a second mask layer 12, and a third mask layer 13 that are sequentially stacked on the second surface of the active layer 110 in the third direction Z.

The second mask layer 12 may include a material having etching selectivity on the first and third mask layers 11 and 13. For example, the first and third mask layers 11 and 13 may include a silicon oxide, and the second mask layer 12 may include a silicon nitride. However, the material included in the first to third mask layers 11, 12, and 13 is not limited thereto, and may be changeable in many ways.

The active layer 110 may be anisotropically etched by using the first mask pattern MP1 as an etching mask

Hence, back gate trenches BG_T may be formed extending at least partially into and/or through the active layer 110 in the third direction Z. The back gate trenches BG_T may expose the fill insulation layer 101, and may be spaced apart from one another at regular intervals in the second direction Y.

Referring to FIG. 19, a first back gate separating pattern 111 and a second back gate separating pattern 113 may be formed on a lower portion (e.g., bottom surface and lower sidewalls) of the back gate trench BG_T, and a back gate insulation pattern 115 and a back gate electrode BG may be formed in the back gate trench BG_T.

In detail, a first back gate separating pattern 111 for conformally covering a bottom side and an internal side of the back gate trench BG_T may be formed, and a second back gate separating pattern 113 may be formed to fill the back gate trench BG_T on which the first back gate separating pattern 111 is formed.

As the first back gate separating pattern 111 and the second back gate separating pattern 113 are partly removed by performing an etch-back process, the first back gate separating pattern 111 and the second back gate separating pattern 113 may be formed on a lower portion of the back gate trench BG_T.

When the back gate insulation pattern 115 is formed to conformally cover the internal side of the back gate trench BG_T in which the first back gate separating pattern 111 and the second back gate separating pattern 113 are formed, the first back gate separating pattern 111, and the second back gate separating pattern 113, a back gate electrode layer for forming the back gate electrodes BG in the back gate trench BG_T may be formed.

The back gate electrodes BG may be formed in the back gate trench BG_T by etching the back gate electrode layer. The back gate electrodes BG may partly fill the back gate trench BG_T.

In one or more embodiments, the back gate insulation pattern 115 may be formed by using at least one of a chemical oxidation method, a thermal oxidation method, an ultraviolet (UV) oxidation method, a dual plasma oxidation method, and an atomic layer deposition (ALD) method. However, the method for forming the back gate insulation pattern 115 is not limited thereto, and may be changeable in many ways.

When forming the back gate insulation pattern 115 by using the above-noted oxidation methods, a surface of the active layer 110 is oxidized so the width of the internal side of the back gate trench BG_T in which the back gate insulation pattern 115 is formed (i.e., between opposing sidewalls of the back gate trench BG_T) may be different from the width of the internal side of the back gate trench BG_T in which the first back gate separating pattern 111 is formed. For example, the width of the internal side of the back gate trench BG_T in which the back gate insulation pattern 115 is formed may be greater than the width of the internal side of the back gate trench BG_T in which the first back gate separating pattern 111 is formed.

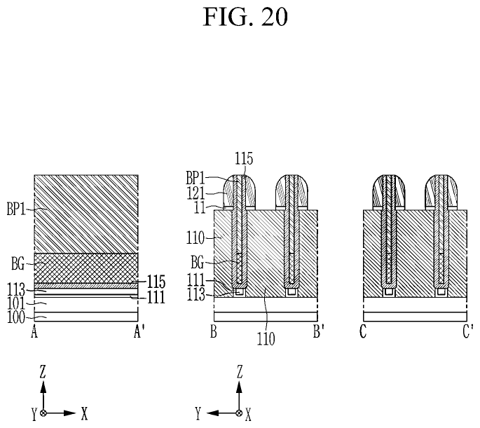

Referring to FIG. 20, a first back gate capping pattern BP1 may be formed to fill the region in the back gate trench BG_T that remains after forming the back gate electrode BG in the back gate trench BG_T.

A gas phase doping (GPD) process or a plasma doping (PLAD) process may be performed before forming the first back gate capping pattern BP1. By this process, impurities may be doped into the active layer 110 through the back gate trench BG_T in which the back gate electrode BG is formed.

An etch-back process or a planarization process may be performed to expose the second mask layer 12 (see FIG. 19) of the first mask pattern MP1, and the second mask layer 12 of the first mask pattern MP1 may be removed.

A spacer film (not shown) for forming a spacer pattern 121 may be formed on an upper side of the first mask layer 11 of the first mask pattern MP1, sides of the back gate insulation pattern 115, and an upper side of the first back gate capping pattern BP1. The widths of the activating patterns AP1 and AP2 of FIG. 2 of the vertical channel transistors may be determined according to a deposited thickness of the spacer film

The spacer film may include an insulating material. The spacer film may include, for example, at least one of a silicon oxide, a silicon oxynitride, a silicon nitride, a silicon carbide (SiC), and a silicon carbon nitride layer (SiCN), although embodiments are not limited thereto.

A pair of spacer patterns 121 separated from each other in the second direction Y may be formed on opposing sides of the back gate insulation pattern 115 by performing an etching process on the spacer film.

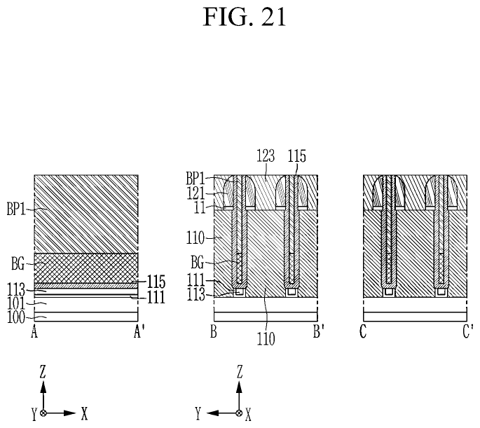

Referring to FIG. 21, a molding pattern 123 may be formed on the second surface of the active layer 110. That is, the molding pattern 123 may be formed on the second surface of the active layer 110 between adjacent spacer patterns 121. For example, the molding pattern 123 may include polysilicon.

A process for forming the molding pattern 123 may include, for example: forming a molding layer (not shown) covering at least a portion of the spacer pattern 121, an upper side of the back gate insulation pattern 115, and an upper side of the first back gate capping pattern BP1; and performing a planarization process to remove a portion of the molding layer.

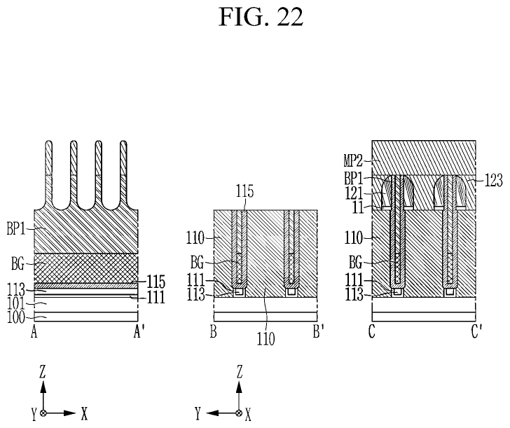

Referring to FIG. 22 together with FIG. 1, a second mask pattern MP2 may be formed on an upper surface of the molding pattern 123, the molding pattern 123 is patterned by using the second mask pattern MP2 as an etching mask, and a portion of the spacer pattern 121 formed on the active layer 110 may be exposed. The exposed spacer pattern 121 may be etched.

In detail, the second mask pattern MP2 formed on the molding pattern 123 may have a pattern extending in the second direction Y and spaced from one another in the first direction X in a plan view. Hence, the molding pattern 123 and the spacer pattern 121 disposed between the second mask pattern MP2 spaced in the first direction X may be exposed, the molding pattern 123 may be etched, and the exposed spacer pattern 121 may be etched.

In the process for etching the exposed spacer pattern 121, the first mask layer 11 between the spacer pattern 121 and the second surface of the active layer 110, and the first back gate capping pattern BP1 and the back gate insulation pattern 115 protruding over the second surface of the active layer 110 may be etched together.

Referring to FIG. 23 and FIG. 24, the second mask pattern MP2 may be removed, and the spacer pattern 121 may be used as an etching mask to perform an anisotropic etching on the active layer 110.

Hence the one pair of first and second activating patterns AP1 and AP2 separated from each other may be formed on respective sides of the back gate insulation pattern 115. The first activating pattern AP1 and the second activating pattern AP2 may be respectively arranged in parallel in the first direction X. As the first and second activating patterns AP1 and AP2 are formed, the fill insulation layer 101 may be exposed.

The widths of the first and second activating patterns AP1 and AP2 in the second direction Y may be substantially the same.

In the process for forming the first and second activating patterns AP1 and AP2 by etching the active layer 110, sides of the first and second activating patterns AP1 and AP2 may be etched to have round shapes approaching an upper surface of each of the first and second activating patterns AP1 and AP2.

In the process for etching the active layer 110, the spacer pattern 121, the first back gate capping pattern BP1, and the back gate insulation pattern 115 may be etched together.

Referring to FIG. 22, as described above, as the height of the first back gate capping pattern BP1 and the back gate insulation pattern 115 in the region exposed by the second mask pattern MP2 in the third direction Z is less than the height of the first back gate capping pattern BP1 and the back gate insulation pattern 115 in the region overlapping the second mask pattern MP2 in the third direction Z, the first back gate capping pattern BP1 and the back gate insulation pattern 115 may define the gap region GR in the process for etching the first back gate capping pattern BP1 and the back gate insulation pattern 115.

As shown in FIG. 24, the gap region GR defined by the back gate insulation pattern 115 and the first back gate capping pattern BP1 may be disposed in the region that does not overlap the first and second activating patterns AP1 and AP2 in the second direction Y in a plan view.

The height of the back gate insulation pattern 115 and the first back gate capping pattern BP1 in the gap region GR in the third direction Z may be less than the height of the back gate insulation pattern 115 and the first back gate capping pattern BP1 in the region that is exclusive of the gap region GR in the third direction Z. That is, steps may be generated between the back gate insulation pattern 115 and the first back gate capping pattern BP1 in the gap region GR and the back gate insulation pattern 115 and the first back gate capping pattern BP1 in the region that is exclusive of the gap region GR.

In detail, while the first back gate capping pattern BP1 is etched together, the first back gate capping pattern BP1 may define the gap region GR in the region of the back gate electrode BG that does not overlap the first and second activating patterns AP1 and AP2 in the second direction Y in a plan view.

The first back gate capping pattern BP1 may include a first portion BP1a for covering the back gate electrode BG, and second portions BP1b extending in the third direction Z from the first portion BP1a. The second portions BP1b of the first back gate capping pattern BP1 may be spaced apart from one another in the first direction X. The height or thickness of the first portion BP1a of the first back gate capping pattern BP1 in the third direction Z may be less than the height or thickness of the second portion BP1b in the third direction Z.

The gap region GR of the first back gate capping pattern BP1 may be defined by the first portion BP1a of the first back gate capping pattern BP1 and the neighboring second portion BP1b. Hence, the gap region GR of the first back gate capping pattern BP1 may have a substantially U-shaped cross-section.

In several embodiments, as shown in FIG. 23, a portion of the active layer 110 overlapping the back gate insulation pattern 115 in the gap region GR in the third direction Z may not be etched but may remain in the process for etching the active layer 110.

Referring to FIG. 25 and FIG. 26, an etching stopping pattern SL and a second back gate capping pattern BP2 may be sequentially formed on the first back gate capping pattern BP1.

First, the etching stopping pattern SL may be formed to conformally cover the internal side (i.e., inner sidewall) of the gap region GR defined by the first back gate capping pattern BP1 and the back gate insulation pattern 115. The etching stopping pattern SL may be conformally formed along the first back gate capping pattern BP1 in the gap region GR and the back gate insulation pattern 115.

The second back gate capping pattern BP2 may be formed on the etching stopping pattern SL. That is, the second back gate capping pattern BP2 may be formed in the gap region GR to at least partially fill the remaining region of the gap region GR in which the etching stopping pattern SL is formed.

The process for forming the etching stopping pattern SL and the second back gate capping pattern BP2 may include an etching process for sequentially depositing insulation layers for forming an etching stopping pattern SL and a second back gate capping pattern BP2 on a front (i.e., upper surface) of a sub-substrate 100, and removing the insulation layers in a region that is exclusive of the gap region GR to form the etching stopping pattern SL and the second back gate capping pattern BP2 in the gap region GR.

The etching process for removing the insulation layers in the region exclusive of the gap region GR to form the etching stopping pattern SL and the second back gate capping pattern BP2 in the gap region GR may include the etch back process or the planarization process.

As shown in FIG. 26, regarding the process for etching insulation layers to form the etching stopping pattern SL and second back gate capping patterns BP2, a side of the second back gate capping pattern BP2 may have a rounded shape extending in a concave manner in the second direction Y toward opposing sidewalls of the second back gate capping pattern BP2.

In one or more embodiments, the first back gate capping pattern BP1 and the second back gate capping pattern BP2 may include different materials. For example, the first back gate capping pattern BP1 may include a silicon oxide, and the second back gate capping pattern BP2 may include at least one of a silicon nitride, a silicon oxynitride, or a low dielectric (low-k) material with a lower dielectric constant than the silicon oxide such as SiBN, SiCN, SiOCH, and SiOC.

In one or more embodiments, the etching stopping pattern SL may include the same material as the first back gate capping pattern BP1, and may include a material that is different from the second back gate capping pattern BP2. For example, the etching stopping pattern SL may include a silicon oxide.

In one or more embodiments, when the first back gate capping pattern BP1 and the second back gate capping pattern BP2 include the same material, the process for forming the etching stopping pattern SL may be omitted. For example, when the first back gate capping pattern BP1 and the second back gate capping pattern BP2 include a silicon oxide, the process for forming the etching stopping pattern SL may be omitted.

Referring to FIG. 27 and FIG. 28, a gate insulation pattern GOX, and a word line conductive layer PWL for forming first and second word lines WL1 and WL2 may be sequentially formed.

In detail, the gate insulation pattern GOX may be formed along sides of the first and second activating patterns AP1 and AP2, upper sides of the first and second back gate capping patterns BP1 and BP2, an upper side of the spacer pattern 121, a side of the active layer 110, and an upper side of the fill insulation layer 101.

The gate insulation pattern GOX may be formed by using at least one of a chemical oxidation method, a thermal oxidation method, an ultraviolet (UV) oxidation method, a dual plasma oxidation method, a physical vapor deposition (PVD) method, a thermal chemical vapor deposition (CVD) method, a low pressure chemical vapor deposition (LP-CVD) method, a plasma-reinforced chemical vapor deposition (PE-CVD) method, and an atomic layer deposition (ALD) method, although embodiments are not limited thereto. For example, the process for forming a gate insulation pattern GOX may include: forming the gate insulation pattern GOX by the above-noted oxidation method, and additionally performing the above-described deposition process.

As shown in FIG. 28, when the sides of the first and second activating patterns AP1 and AP2 have round curved surfaces in a plan view, the gate insulation pattern GOX extending along the sides of the first and second activating patterns AP1 and AP2 may also include round curved surfaces; that is, the gate insulation pattern GOX, extending in the first direction X, may follow a contour of the sides of the first and second activating patterns AP1 and AP2.

Further, a first width W1 of the gate insulation pattern GOX in the second direction Y, extending along the sides of the first and second activating patterns AP1 and AP2 may be greater than a second width W2 of the gate insulation pattern GOX in the second direction Y, extending along a side of the second back gate capping pattern BP2.

As the first and second activating patterns AP1 and AP2 and the second back gate capping pattern BP2 include different materials, the thickness or width of the gate insulation pattern GOX formed on the sides of the first and second activating patterns AP1 and AP2 may be different from the thickness or width of the gate insulation pattern GOX formed on the sides of the second back gate capping pattern BP2 in the process for forming a gate insulation pattern GOX.

The word line conductive layer PWL may be formed on the gate insulation pattern GOX. As shown in FIG. 28, the word line conductive layer PWL extending along the gate insulation pattern GOX may include a body portion PWL_B extending in the first direction X and protrusions PWL_P extending in the second direction Y from the body portion PWL_B. The respective protrusions PWL_P of the word line conductive layer PWL may be between a pair of the first activating pattern AP1 adjacent to each other in the first direction X and between a pair of the second activating pattern AP2 adjacent to each other in the first direction X. However, an arrangement and/or shape of the word line conductive layer PWL is not limited thereto, and the word line conductive layer PWL may have various types of structures according to patterning shapes of the first and second back gate capping patterns BP1 and BP2 described with reference to FIG. 26.

The body portion PWL_B and the protrusions PWL_P of the word line conductive layer PWL may correspond to the body portions (WL1_B and WL2_B of FIG. 5) and the protrusions (WL1_P and WL2_P of FIG. 5) of the first and second word lines (WL1 and WL2 of FIG. 5).

Referring to FIG. 29, a first gate separating pattern 153 is formed on the word line conductive layer PWL, and the first gate separating pattern 153 may be etched to remove a portion of the word line conductive layer PWL.

In detail, the first gate separating pattern 153 may cover the word line conductive layer PWL. The first gate separating pattern 153 may at least partially fill a space between adjacent word line conductive layers PWL.

As an anisotropic etching and etch-back process is performed on the first gate separating pattern 153 to remove a portion of the first gate separating pattern 153 before removing a portion of the word line conductive layer PWL, the portion of the word line conductive layer PWL may be exposed.

An etching process may be performed on the exposed word line conductive layer PWL. Hence, as the portion of the word line conductive layer PWL on an upper side of the second back gate capping pattern BP2 is removed, the word line conductive layer PWL may be separated and may be disposed on respective sides of the back gate electrode BG. Further, the word line conductive layer PWL may have a substantially U-shaped cross-section between the first and second activating patterns AP1 and AP2.

Upper sides of the word line conductive layers PWL on the respective sides of the back gate electrode BG may be on a higher level than the upper side of the back gate electrode BG in the third direction Z, relative to an upper surface of the sub-substrate 100 serving as a base reference layer. That is, the height of the word line conductive layer PWL in the third direction Z may be greater than the height of the back gate electrode BG in the third direction Z.

In the process for etching a portion of the word line conductive layer PWL, as the first and second back gate capping patterns BP1 and BP2 are on the back gate electrode BG, it may be prevented to expose the back gate electrode BG or damage the back gate electrode BG while etching the word line conductive layer PWL.

Further, as the first and second back gate capping patterns BP1 and BP2 are on the back gate electrode BG, the word line conductive layer PWL may be etched to have various types of structures while not exposing the back gate electrode BG. For example, a portion of the word line conductive layer PWL may be etched so that the upper side of the word line conductive layer PWL may be on a higher level than the upper side of the back gate electrode BG in the third direction Z, relative to the upper surface of the sub-substrate 100.

Referring to FIG. 30, a second gate separating pattern 155 is formed on an upper surface of the gate separating pattern 153, and a polysilicon layer 161, a first metal layer 163, a second metal layer 165, and a bit line hard mask layer 167 may be sequentially formed on an upper surface of the second gate separating pattern 155 in the third direction Z.

In detail, the second gate separating pattern 155 may be formed to cover the word line conductive layer PWL and the first gate separating pattern 153. The first gate separating pattern 153 and the second gate separating pattern 155 may include different materials, respectively.

The planarization process may be performed when the second gate separating pattern 155 is formed. Hence, the first and second back gate capping patterns BP1 and BP2, the first and second activating patterns AP1 and AP2, the second gate separating pattern 155, the back gate insulation pattern 115, the etching stopping pattern SL, and the gate insulation pattern GOX may have substantially planar upper sides; that is, the first and second back gate capping patterns BP1 and BP2, the first and second activating patterns AP1 and AP2, the second gate separating pattern 155, the back gate insulation pattern 115, the etching stopping pattern SL, and the gate insulation pattern GOX may be substantially coplanar in the third direction Z.

In the planarization process, the first mask layer 11 and the spacer pattern 121 disposed on the first and second activating patterns AP1 and AP2 may be removed and the upper sides of the first and second activating patterns AP1 and AP2 may be exposed. Further, in the planarization process, the gate insulation pattern GOX on the first and second back gate capping patterns BP1 and BP2 may be removed together.

The polysilicon layer 161 may be formed on a front (i.e., the upper surface) of the sub-substrate 100. The polysilicon layer 161 may be formed on the first and second activating patterns AP1 and AP2, the first and second back gate capping patterns BP1 and BP2, the second gate separating pattern 155, the back gate insulation pattern 115, the etching stopping pattern SL, and the gate insulation pattern GOX, and may contact the upper sides of the first and second activating patterns AP1 and AP2.

The first metal layer 163, the second metal layer 165, and the bit line hard mask layer 167 may be sequentially formed on the polysilicon layer 161 in the third direction Z.

The polysilicon layer 161 may include impurity-doped polysilicon, and the first metal layer 163 and the second metal layer 165 may include conductive materials. For example, the first metal layer 163 may include a conductive metal nitride (e.g., a titanium nitride, a tantalum nitride, etc.), and the second metal layer 165 may include a metal (e.g., tungsten, titanium, tantalum, etc.). At least one of the first metal layer 163 and the second metal layer 165 may include a metal silicide such as a titanium silicide, a cobalt silicide, or a nickel silicide. However, the materials included by the first metal layer 163 and the second metal layer 165 are not limited thereto, and may be changeable in many ways.

The bit line hard mask layer 167 may include an insulating material such as a silicon nitride or a silicon oxynitride.

Referring to FIG. 31, the polysilicon layer 161, the first metal layer 163, the second metal layer 165, and the bit line hard mask layer 167 may be patterned to form bit lines BL extending in the second direction Y and separated from one another in the first direction X. Further, the polysilicon layer 161, the first metal layer 163, the second metal layer 165, and the bit line hard mask layer 167 may be sequentially stacked in the third direction Z to configure the bit line BL.

In the process for forming bit lines BL, a portion of the second back gate capping pattern BP2 may be etched together, and a portion of the second back gate capping pattern BP2 may be recessed toward the sub-substrate 100 from the upper side. Differing from what is shown in FIG. 31, in the process for forming the bit lines BL, a portion of the second gate separating pattern 155 may be etched together.

Referring to FIG. 32, a spacer insulation layer 171 for defining a gap region may be formed between the bit lines BL when the bit lines BL are formed.

The spacer insulation layer 171 may be conformally formed on the front of the sub-substrate 100. The deposition thickness of the spacer insulation layer 171 may be less than a half of the interval between the adjacent bit lines BL. As the spacer insulation layer 171 is deposited as described above, gap regions may be defined between the respective bit lines BL. The gap regions may extend in the second direction Y in parallel to the bit lines BL.

A shield pattern SP may be formed on the spacer insulation layer 171. The shield pattern SP may be conformally formed on the front of the sub-substrate 100.

The shield pattern SP may fill the gap regions of the spacer insulation layer 171 and may be conformally formed on the spacer insulation layer 171. When the shield pattern SP is deposited on the spacer insulation layer 171 by using the chemical vapor deposition (CVD) method, a discontinuous boundary surface, for example, a seam may be formed in the gap regions by a step coverage property. An etch-back or other process may be used to planarize an upper surface of the shield pattern SP.

The shield pattern SP may, for example, include a metallic material such as tungsten (W), titanium (Ti), nickel (Ni), or cobalt (Co). For another example, the shield pattern SP may include a conductive two-dimensional (2D) material such as graphene.

A shield capping pattern 173 may be formed on the shield pattern SP. The shield capping pattern 173 may conformally cover the shield pattern SP. The shield capping pattern 173 may, for example, include a silicon nitride layer.

Referring to FIG. 32 and FIG. 33, the sub-substrate 100 on which the back gate electrodes BG, the first and second word lines WL1 and WL2, the first and second activating patterns AP1 and AP2, the bit lines BL, and the shield pattern SP are formed may be bonded to (or otherwise attached to) the substrate 200 on which the peripheral circuit structure body PS is formed. For example, the sub-substrate 100 may be bonded to the substrate 200 by using a dielectric bonding method or a hybrid bonding method. The sub-substrate 100 may be bonded to the substrate 200 by the bonding insulation layer 221. The shield capping pattern 173 may directly contact the bonding insulation layer 221.

When the sub-substrate 100 is bonded to the substrate 200, a back side lapping process for removing the sub-substrate 100 may be performed. The process for removing the sub-substrate 100 may include exposing the fill insulation layer 101 by sequentially performing a grinding process and a dry etching process.

The fill insulation layer 101, a portion of the first back gate separating pattern 111, and a portion of the gate insulation pattern GOX may be removed to expose the word line conductive layer PWL and the first and second activating patterns AP1 and AP2.

The fill insulation layer 101 may be etched by performing a wet or dry etching process, and the first back gate separating pattern 111 and the gate insulation pattern GOX may be etched by performing the etch-back process.

First and second word lines WL1 and WL2 may be formed by performing an etching process on the word line conductive layer PWL and separating the word line conductive layer PWL (e.g., by using a standard photolithographic process). Bottom surfaces of the first and second word lines WL1 and WL2 may be on a lower level than the bottom surface of the back gate electrode BG, in the third direction Z relative to an upper surface of the substrate 200 serving as a base reference layer, and upper sides of the first and second word lines WL1 and WL2 may be on a higher level than the upper side of the back gate electrode BG in the third direction Z relative to the upper surface of the substrate 200. The upper sides of the first and second word lines WL1 and WL2 may be on a lower level than the upper side of the first gate separating pattern 153 in the third direction Z.

A gate capping pattern 175 may be formed in the first and second word lines WL1 and WL2. The gate capping pattern 175 may fill a region in which a portion of the word line conductive layer PWL is removed. That is, the gate capping pattern 175 may cover the first and second word lines WL1 and WL2 and the first gate separating pattern 153.

The process for forming the gate capping pattern 175 may include performing a planarization process so that the gate capping pattern 175 may have an upper side that is substantially planar to the first and second back gate separating patterns 111 and 113 after forming an insulating material for forming the gate capping pattern 175.

A contact pattern BC extending in the third direction Z at least partially into or through the contact interlayer insulating layer 243 and connected to the first and second activating patterns AP1 and AP2 may be formed. The process for forming the contact patterns BC may include: patterning the contact interlayer insulating layer 243 to form holes for exposing the first and second activating patterns AP1 and AP2; depositing a conductive layer at least partially filling the holes; and planarizing the conductive layer to expose the upper side of the contact interlayer insulating layer 243.

Landing pads LP connected to the respective contact patterns BC may be formed. The process for forming the landing pads LP may include forming landing pads LP by using mask patterns; and forming a pad separating insulation pattern 245 by filling an insulating material between the landing pads LP. The upper side of the pad separating insulation pattern 245 may form a substantially coplanar side with the upper sides of the landing pads LP. An order and a method for forming the landing pads LP and the pad separating insulation pattern 245 are not limited thereto and may be modifiable in many ways. For example, the pad separating insulation pattern 245 may be formed and patterned, and landing pads LP may be formed between the pad separating insulation pattern 245.

As shown in FIG. 2, a contact etch stopping layer 247 may be formed on the landing pads LP and the pad separating insulation pattern 245, it may penetrate (i.e., extend in the third direction Z at least partially into or through) the contact etch stopping layer 247, and a storage electrode 251 electrically connected to the respective landing pads LP may be formed.

A capacitor dielectric layer 253 for conformally covering a surface of the storage electrodes 251 may be formed and a plate electrode 255 may be formed on the dielectric layer 253 to thus form a data storage pattern DSP.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A semiconductor device, comprising:
a substrate;
a bit line on the substrate and extending in a first direction parallel to an upper surface of the substrate;
a first word line on the bit line, the first word line extending in a second direction parallel to the upper surface of the substrate and crossing the first direction;
a second word line on the bit line, the second word line extending in the second direction and spaced from the first word line in the first direction;
first activating patterns on the bit line and spaced in the second direction between the first word line and the second word line;
second activating patterns on the bit line and spaced from the first activating patterns in the first direction between the first word line and the second word line;
a back gate electrode crossing the bit line and extending in the second direction between the first activating patterns and the second activating patterns; and
a first back gate capping pattern and second back gate capping pattern at least partially overlapping the back gate electrode in a plan view,
wherein the first back gate capping pattern defines a gap region on the back gate electrode not overlapping the first activating patterns and the second activating patterns in the first direction, and
the second back gate capping pattern is in the gap region.

2. The semiconductor device of claim 1, wherein
the first back gate capping pattern and the second back gate capping pattern include different materials.

3. The semiconductor device of claim 2, further comprising
an etching stopping pattern between the first back gate capping pattern and the second back gate capping pattern and including a same material as the first back gate capping pattern.

4. The semiconductor device of claim 3, wherein
the first back gate capping pattern and the second back gate capping pattern are alternately disposed in the first direction on the back gate electrode, and
the etching stopping pattern directly contacts the back gate electrode.

5. The semiconductor device of claim 1, wherein
the first back gate capping pattern and the second back gate capping pattern include a same material.

6. The semiconductor device of claim 5, further comprising
a first etching stopping pattern and a second etching stopping pattern, the first and second etching stopping patterns being between the first back gate capping pattern and the second back gate capping pattern and including different materials,
wherein the first etching stopping pattern includes a same material as the first back gate capping pattern and the second back gate capping pattern.

7. The semiconductor device of claim 6, wherein
the semiconductor device includes an air gap between the first etching stopping pattern and the second back gate capping pattern.

8. The semiconductor device of claim 1, further comprising
a gate insulation pattern between the first word line and first activating patterns and between the second word line and the second activating patterns.

9. The semiconductor device of claim 8, wherein
the gate insulation pattern is further between the first word line and the second back gate capping pattern and between the second word line and the second back gate capping pattern.

10. The semiconductor device of claim 1, wherein
the first word line and the second word line respectively include
a body portion extending in the second direction, and
protrusions extending in the first direction toward the back gate electrode from the body portion and between the first activating patterns spaced in the second direction and between the second activating patterns spaced in the second direction,
each of the first activating patterns and the second activating patterns respectively includes a first surface and a second surface opposite the first surface, the first surface facing the back gate electrode and the second surface facing the first word line and the second word line, and
respective ends of the second surfaces of the first activating patterns and the second activating patterns include rounded portions.

11. The semiconductor device of claim 10, wherein
ends of the protrusions are between the first surface and the second surface of the first and second activating patterns in a plan view.

12. The semiconductor device of claim 10, wherein
ends of the protrusions are substantially on a same boundary as the first surface or the second surface of the first and second activating patterns in a plan view.

13. A semiconductor device, comprising:
a substrate;
bit lines on the substrate and extending in a first direction parallel to an upper surface of the substrate;
word lines on the bit lines and extending in a second direction parallel to the upper surface of the substrate and crossing the first direction and spaced in the first direction;
activating patterns on the bit lines and spaced apart from one another in the first direction and the second direction between the word lines;
a back gate electrode crossing the bit lines between the activating patterns and extending in the second direction; and
a first back gate capping pattern and a second back gate capping pattern at least overlapping the back gate electrode,
wherein each of the respective word lines includes:
a body portion extending in the second direction; and
protrusions extending from the body portion in the first direction toward the back gate electrode and between the activating patterns spaced in the second direction,
and wherein the first back gate capping pattern defines a gap region between the protrusions spaced in the first direction on the back gate electrode, and
the second back gate capping pattern is in the gap region.

14. The semiconductor device of claim 13, wherein
the first back gate capping pattern and the second back gate capping pattern include different materials, and
the semiconductor device further includes an etching stopping pattern between the first back gate capping pattern and the second back gate capping pattern and including a same material as the first back gate capping pattern.

15. The semiconductor device of claim 14, further comprising
a gate insulation pattern between the word lines and the activating patterns and between the word lines and the second back gate capping pattern,
wherein a first width of the gate insulation pattern between the word lines and the activating patterns is greater than a second width of the gate insulation pattern between the word lines and the second back gate capping pattern.

16. The semiconductor device of claim 13, wherein
the back gate electrode and the word lines respectively include a first surface and a second surface opposite the first surface, the first surface facing the bit lines and the second surface facing the first surface in a vertical direction perpendicular to the upper surface of the substrate,
the first surface of the back gate electrode and the first surface of each of the word lines are on different levels in the vertical direction relative to the upper surface of the substrate as a base reference layer, and
the second surface of the back gate electrode and the second surface of the word lines are on different levels in the vertical direction relative to the upper surface of the substrate.

17. The semiconductor device of claim 16, wherein
the first surface of each of the word lines is nearer to the bit lines in the vertical direction than the first surface of the back gate electrode, and
the second surface of each of the word lines is further spaced from the bit lines in the vertical direction than the second surface of the back gate electrode.

18. The semiconductor device of claim 16, wherein
the first back gate capping pattern includes
a first portion at least partially covering the first surface of the back gate electrode, and
second portions extending in the vertical direction from the first portion and spaced in the first direction with the second back gate capping pattern therebetween, and
the gap region of the first back gate capping pattern is defined by the first portion and the second portions adjacent to each other.

19. The semiconductor device of claim 18, further comprising
a shield pattern crossing the protrusions between the bit lines and extending in the first direction,
wherein the first back gate capping pattern and the second back gate capping pattern are between the back gate electrode and the shield pattern,
the second portion of the first back gate capping pattern at least partially overlaps the bit lines in a plan view, and
the second back gate capping pattern at least partially overlaps the shield pattern in a plan view.

20. A semiconductor device, comprising:
a substrate;
a peripheral circuit structure body including peripheral circuits on the substrate and a peripheral circuit insulation layer at least partially covering the peripheral circuits;
bit lines on the peripheral circuit structure body and extending in a first direction parallel to an upper surface of the substrate;
word lines on the bit lines and extending in a second direction parallel to the upper surface of the substrate and crossing the first direction on the bit lines, the word lines spaced apart from each other in the first direction;
activating patterns on the bit lines and between the word lines, the activating patterns spaced apart from each other in the first direction and the second direction;
a back gate electrode crossing the bit lines between the activating patterns and extending in the second direction; and
a first back gate capping pattern and a second back gate capping pattern at least partially overlapping the back gate electrode and including different materials,
wherein each of the word lines include
a body portion extending in the second direction, and
protrusions extending from the body portion in the first direction toward the back gate electrode and between the activating patterns spaced in the second direction,
each of the back gate electrode and the word lines respectively includes a first surface and a second surface opposite the first surface, the first surface facing the bit lines and the second surface facing the first surface in a vertical direction,
the first surfaces of the word lines are nearer to the bit lines than the first surface of the back gate electrode,
the first back gate capping pattern includes
a first portion at least partially covering the first surface of the back gate electrode, and
second portions extending in a vertical direction from the first portion and spaced in the first direction with the second back gate capping pattern therebetween,
the first back gate capping pattern includes a gap region between the protrusions and defined by the first portion of the first back gate capping pattern and the second portions adjacent to each other, and
the second back gate capping pattern is in the gap region.
